(19) United States
(12) Patent Application Publication
(10) Pub. No.: US 2026/0343839 A1
(43) Pub. Date: Oct. 29, 2026

(54) ELECTRONIC DEVICE INCLUDING STRUCTURE FOR PROTECTING DISPLAY DRIVING CIRCUIT FROM STATIC ELECTRICITY

(71) Applicant: Samsung Electronics Co., Ltd., Suwon-si (KR)

(72) Inventors: Semin KIM, Suwon-si (KR); Youngsuk KIM, Suwon-si (KR); Chanyoung KIM, Suwon-si (KR); Jungchul AN, Suwon-si (KR); Jaehoon LEE, Suwon-si (KR)

(21) Appl. No.: 19/632,865

(22) Filed: Mar. 30, 2026

Related U.S. Application Data
(63) Continuation of application No. PCT/KR2026/004835, filed on Mar. 26, 2026.

(30) Foreign Application Priority Data
Mar. 28, 2025 (KR) 10-2025-0040390
Jun. 2, 2025 (KR) 10-2025-0072232
Aug. 25, 2025 (KR) 10-2025-0118392

(51) Int. Cl. H05K 9/00; H04M 1/02

(52) U.S. Cl. CPC H05K 9/0067; H04M 1/0222; H04M 1/0277

(57) ABSTRACT

An electronic device includes a structure configured to protect a display driving circuit from static electricity. The display module may include a display driving circuit, an FPCB covering the display driving circuit, and a waterproof tape attaching one end of the FPCB to an extension region of a display panel. The FPCB may include a first cover layer forming a first surface facing the display driving circuit, a second cover layer forming a second surface opposite to the first surface, and at least one metal layer disposed between the first cover layer and the second cover layer. The first cover layer may include at least one first slit disposed adjacent to the display driving circuit and exposing a portion of the at least one metal layer.

### CROSS-REFERENCE TO RELATED APPLICATIONS

This application is a continuation of International Application No. PCT/KR2026/004835 designating the United States, filed on Mar. 26, 2026,in the Korean Intellectual Property Receiving Office and claiming priority to Korean Patent Application Nos. 10-2025-0040390, filed on Mar. 28, 2025, 10-2025-0072232, filed on Jun. 2, 2025, and 10-2025-0118392, filed on Aug. 25, 2025, in the Korean Intellectual Property Office, the disclosures of each of which are incorporated by reference herein in their entireties.

### BACKGROUND

### Field

The disclosure relates to an electronic device including a structure configured to protect a display driving circuit from static electricity.

### DESCRIPTION OF RELATED ART

A foldable electronic device may include a hinge device, and first and second housings movably connected to each other via the hinge device. The foldable electronic device allows the first housing to rotate relative to the second housing within a range of 0 to 360 degrees via the hinge device enabling operation in an in-folding and/or out-folding manner. For example, the foldable electronic device may include a flexible display disposed to cross the first housing and the second housing in an open state of 180 degrees.

The flexible display may include a bendable display panel. The display panel may include a bending portion, which extends to one side and is electrically connected (e.g., grounded) to a conductive plate disposed on the rear surface of the flexible display, and in which a control circuit is disposed. For example, when a flexible display is disposed in a foldable electronic device and the display panel is viewed from above, the bending portion may protrude outward beyond an edge of the display panel.

The above-described information may be provided as related art for the purpose of helping to understand the disclosure. No assertion or determination is made regarding whether any of the foregoing may be applied as prior art with respect to the disclosure.

In the foldable electronic device, static electricity introduced from the outside may be introduced into the foldable electronic device through an edge of the flexible display. Such static electricity may not flow into a conductive plate electrically connected to a main ground of the electronic device through the bending portion, but may directly or indirectly affect the display panel and the display driving circuit (e.g., a driver display IC (DDI)), thereby causing malfunction such as blackening of the display panel or shorting of some data lines.

### SUMMARY

Embodiments of the disclosure may provide an electronic device including a structure configured to protect a display driving circuit from static electricity.

According to an example embodiment, an electronic device may include: a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and at configured to be least partially bent, and an extension region extending from the bending region to a rear surface of the display module. The display module may include a display driving circuit (display driver IC (DDI)) disposed on the extension region of the display panel, a flexible printed circuit board (FPCB) bonded to a portion of the extension region of the display panel and extending in a first direction of the display module in which the bending region is located to cover the display driving circuit, and a waterproof tape attaching one end of the FPCB to the extension region of the display panel. The FPCB may include a first cover layer forming a first surface facing the display driving circuit, a second cover layer forming a second surface opposite to the first surface, and at least one metal layer disposed between the first cover layer and the second cover layer. The first cover layer may include at least one first slit disposed adjacent to the display driving circuit and exposing a portion of the at least one metal layer.

According to an example embodiment, an electronic device may include: a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and configured to be at least partially bent, and an extension region extending from the bending region to a rear surface of the display module. The display module may include a display driving circuit (display driver IC (DDI)) disposed on the extension region of the display panel, an FPCB bonded to a portion of the extension region of the display panel and extending in a first direction of the display module in which the bending region is located to cover the display driving circuit, a waterproof tape attaching one end of the FPCB to the extension region of the display panel, and a conductive member comprising a conductive material disposed adjacent to the waterproof tape.

According to an example embodiment, an electronic device may include: a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and configured to be at least partially bent, and an extension region extending from the bending region to a rear surface of the display module. The display module may include a display driving circuit (display driver IC (DDI)) disposed on the extension region of the display panel, an FPCB bonded to a portion of the extension region of the display panel and extending in a first direction of the display module in which the bending region is located to cover the display driving circuit, a waterproof tape attaching one end of the FPCB to the extension region of the display panel, and a cover disposed between the FPCB and the display driving circuit.

According to various example embodiments of the disclosure, a product lifespan may be extended and malfunction such as blackening of a display panel or shorting of some data lines may be reduced by protecting the display driving circuit from static electricity.

In addition, various effects that are directly or indirectly identified through the disclosure may be provided.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a block diagram of an example electronic device in a network environment according to various embodiments.

FIGS. 2A and 2B are diagrams illustrating front and rear views of an example electronic device in an unfolded state according to various embodiments.

FIGS. 3A and 3B are diagrams illustrating front and rear views of the electronic device in a folded state according to various embodiments.

FIG. 4 is an exploded perspective view of an electronic device according to various embodiments.

FIG. 5 is an exploded perspective view of a display module according to various embodiments.

FIG. 6 is a diagram illustrating a rear view of a configuration of a display module according to various embodiments.

FIGS. 7 and 8 are partial cross-sectional views of an electronic device illustrating an edge of a display module according to a comparative example.

FIG. 9 is a diagram illustrating a wiring structure of an FPCB a lifting phenomenon of a waterproof tape according to a comparative example.

FIG. 10 is a diagram illustrating a wiring structure of a FPCB, configured to reduce a lifting phenomenon of the waterproof tape according to various embodiments.

FIGS. 11, 12 and 13 are diagrams illustrating an example configuration of a rear surface of a display module according to various embodiments.

FIGS. 14, 15, 16, 17 and 18 are partial cross-sectional views of an electronic device each illustrating an edge of a display module according to various embodiments.

FIG. 19 is a diagram illustrating an example configuration of a rear surface of a display module further including a cover member according to various embodiments.

FIGS. 20 and 21 are partial cross-sectional views of an electronic device illustrating an edge of the display module of FIG. 19 according to various embodiments.

FIG. 22 is a partial cross-sectional view of an electronic device illustrating an edge of a display module according to a comparative example.

FIGS. 23, 24 and 25 are partial cross-sectional views of an electronic device each illustrating an edge of a display module according to various embodiments.

### DETAILED DESCRIPTION

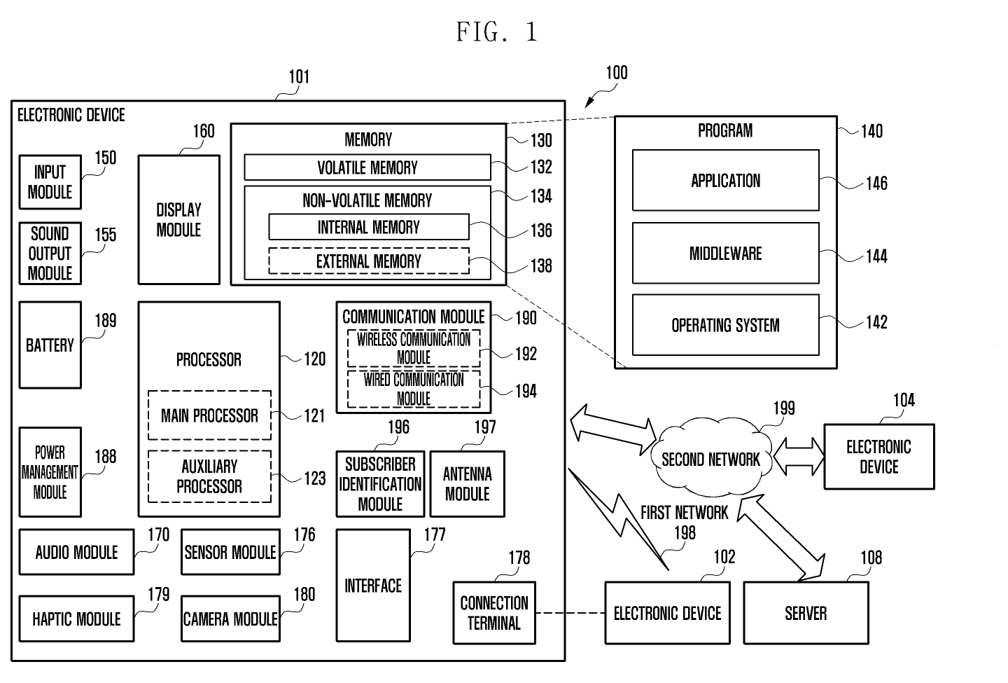

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one of the components (e.g., the connecting terminal 178) may be omitted from the electronic device 101, or one or more other components may be added in the electronic device 101. In various embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121. Thus, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited /disclosed functions, e.g., in a distributed manner. At least one processor may execute program instructions to achieve or perform various functions,

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth^{TM}, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20Gbps or more) for implementing eMBB, loss coverage (e.g., 164dB or less) for implementing mMTC, or U-plane latency (e.g., 0.5ms or less for each of downlink (DL) and uplink (UL), or a round trip of 1ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B," "at least one of A and B," "at least one of A or B," "A, B, or C," "at least one of A, B, and C," and "at least one of A, B, or C," may include any one of, or all possible combinations of the items enumerated together in a corresponding one of the phrases. As used herein, such terms as "1st" and "2nd," or "first" and "second" may be used to simply distinguish a corresponding component from another, and does not limit the components in other aspect (e.g., importance or order). It is to be understood that if an element (e.g., a first element) is referred to, with or without the term "operatively" or "communicatively", as "coupled with," "coupled to," "connected with," or "connected to" another element (e.g., a second element), the element may be coupled with the other element directly (e.g., wiredly), wirelessly, or via a third element.

As used in connection with various embodiments of the disclosure, the term "module" may include a unit implemented in hardware, software, or firmware, or any combination thereof, and may interchangeably be used with other terms, for example, "logic," "logic block," "part," or "circuitry". A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

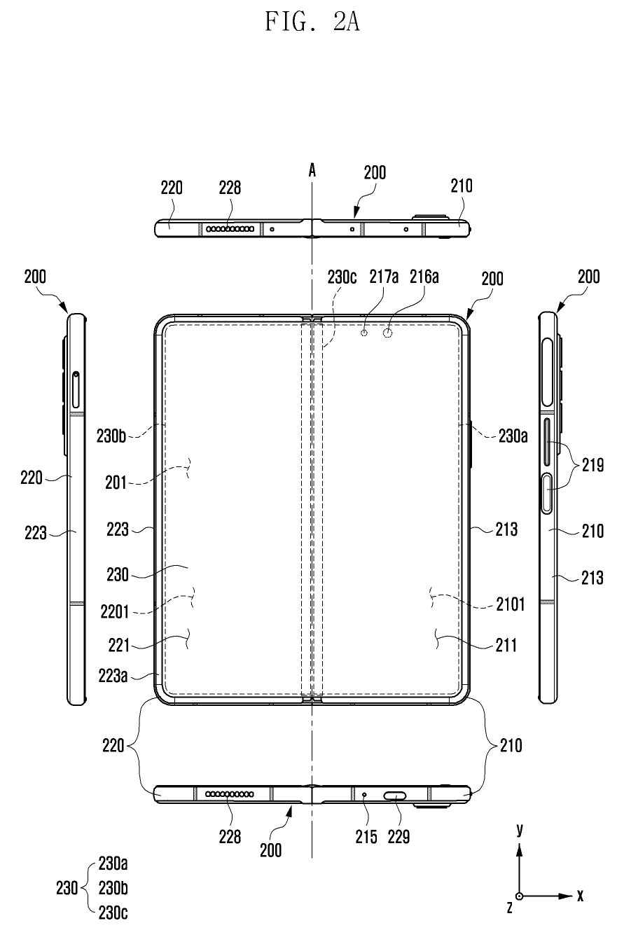

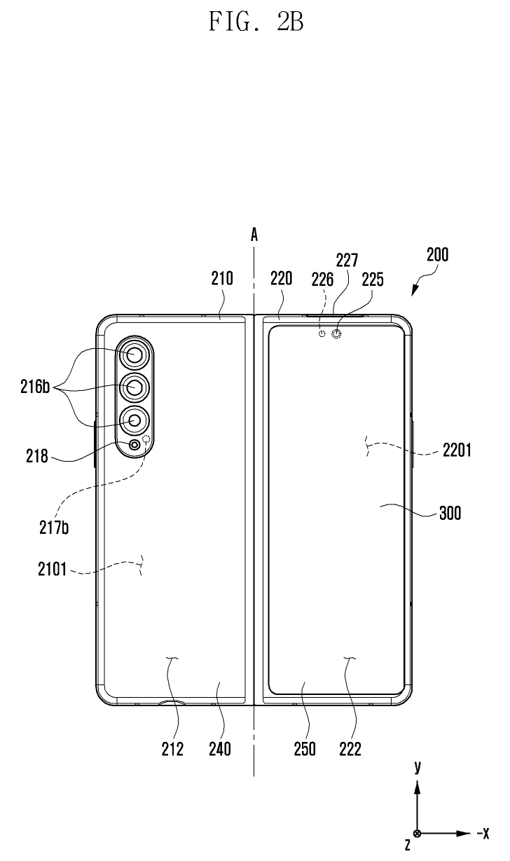

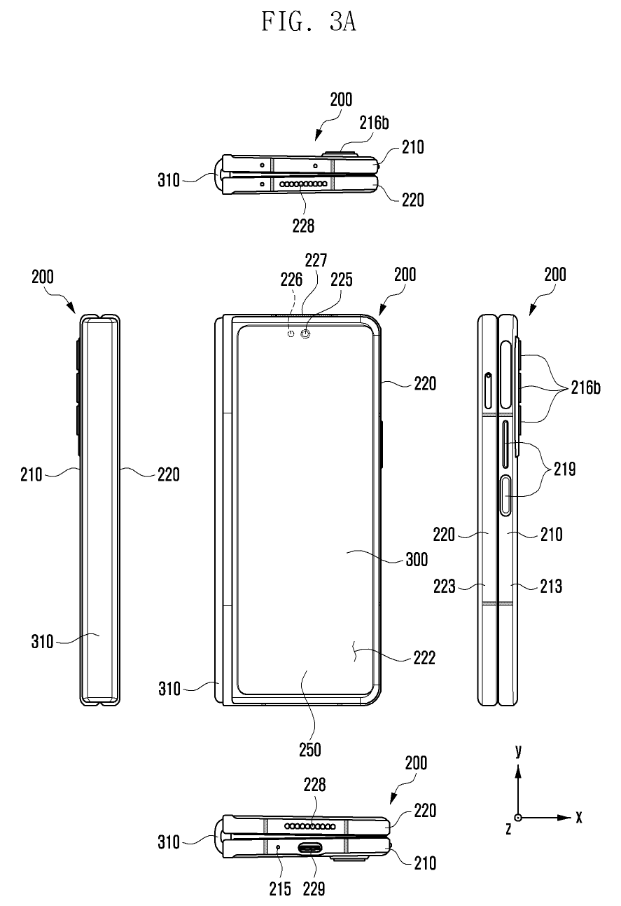

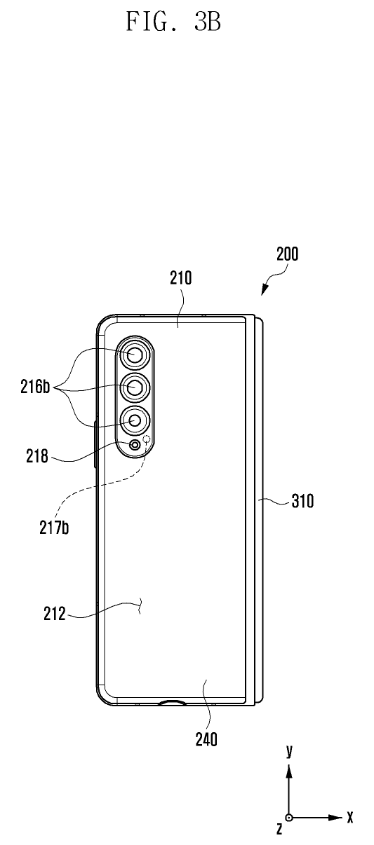

FIGS. 2A and 2B are diagrams illustrating front and rear views of an example electronic device in an unfolded state according to various embodiments. FIGS. 3A and 3B are diagrams illustrating front and rear views of the electronic device in a folded state according to various embodiments.

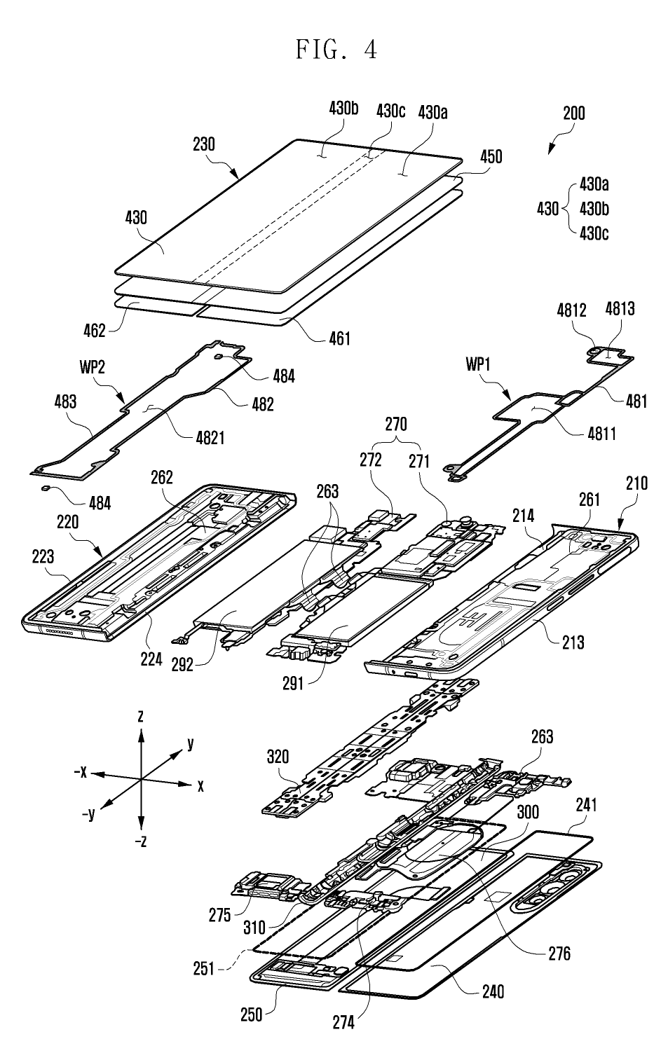

Referring to FIGS. 2A to 3B, an electronic device 200 (e.g., the electronic device 101 of FIG. 1) may include a pair of housings 210 and 220 (e.g., a foldable housing structure) coupled to each other via a hinge device (e.g., the hinge device 320 in FIG. 4) (e.g., a hinge module) to be rotatable about a folding axis A so as to be foldable relative to each other, a first display 230 (e.g., a flexible display, a foldable display, or a main display) disposed on the pair of housings 210 and 220, and/or a second display 300 (e.g., a sub-display) disposed on a second housing 220. According to an embodiment, at least a portion of the hinge device (e.g., the hinge device 320 of FIG. 4) may be disposed so as to be invisible from the outside through a first housing 210 and a second housing 220, and, in an unfolded state, may be disposed so as to be invisible from the outside through a hinge housing 310 that covers a foldable portion. According to an embodiment, the hinge device 320 may include a gear assembly including a plurality of gears, hinge shafts coupled to the gear assembly and rotated through the gear assembly, a hinge module including a plurality of hinge cams performing a cam-interlocking operation, and hinge plates connecting the hinge module to the first housing 210 and the second housing 220. In the disclosure, a surface on which a first display 230 is disposed may be defined as a front surface of the electronic device 200, and a surface opposite to the front surface may be defined as a rear surface of the electronic device 200. In addition, the surface surrounding the space between the front surface and the rear surface may be defined as the side surface of the electronic device 200.

According to various embodiments, the pair of housings 210 and 220 may include a first housing 210 and a second housing 220 that are foldably arranged with respect to each other through the hinge device (e.g., the hinge device 320 of FIG. 4). According to an embodiment, the pair of housings 210 and 220 are not limited to the shape and assembly illustrated in FIGS. 2A-3B, but may be implemented by other shapes or other combinations and/or assemblies of components. According to an embodiment, the first housing 210 and the second housing 220 may be disposed on both sides with respect to a folding axis A and may have a shape that is generally symmetrical with respect to the folding axis A. In various embodiments, the first housing 210 and the second housing 220 may be folded asymmetrically with respect to the folding axis A. According to an embodiment, the first housing 210 and the second housing 220 may have different angles or distances relative to each other depending on whether the electronic device 200 is in an unfolded state, a folded state, or an intermediate state.

According to various embodiments, in the unfolded state of the electronic device 200, the first housing 210 may be connected to the hinge device (e.g., the hinge device 320 of FIG. 4) and may include a first surface 211 disposed to face the front of the electronic device 200, a second surface 212 facing away from the first surface 211, and/or a first side surface member 213 surrounding at least a portion of a first space between the first surface 211 and the second surface 212. According to an embodiment, in the unfolded state of the electronic device 200, the second housing 220 may be connected to the hinge device (e.g., the hinge device 320 of FIG. 4) and may include a third surface 221 disposed to face the front of the electronic device 200, a fourth surface 222 oriented in a direction opposite to the third surface 221, and/or a second side surface member 223 surrounding at least a portion of a second space between the third surface 221 and the fourth surface 222. According to an embodiment, the first surface 211 may be oriented substantially in the same direction as the third surface 221 in the unfolded state and may at least partially face the third surface 221 in the folded state. According to an embodiment, the electronic device 200 may further include a recess 201 formed to accommodate the first display 230 through structural coupling between the first housing 210 and the second housing 220. According to an embodiment, the recess 201 may have substantially the same size as the first display 230. According to an embodiment, the first housing 210 may include a first protective frame 213a (e.g., a first decoration member) coupled to a first side surface member 213 and overlapping an edge of the first display 230 so as to cover the edge of the first display 230 from being visible from the outside, when viewed from above the first display 230. According to an embodiment, the first protective frame 213a may be integrally formed with the first side surface member 213. According to an embodiment, the second housing 220 may include a second protective frame 223a (e.g., a second decoration member) coupled to a second side surface member 223 and overlapping an edge of the first display 230 so as to cover the edge of the first display 230 from being visible from the outside, when viewed from above the first display 230. According to an embodiment, the second protective frame 223a may be integrally formed with the second side surface member 223. In various embodiments, the first protective frame 213a and the second protective frame 223a may be omitted.

According to various embodiments, the hinge housing 310 (e.g., a hinge cover) may be disposed between the first housing 210 and the second housing 220, and may be arranged to cover a portion (e.g., at least one hinge module) of a hinge device (e.g., the hinge device 320 of FIG. 4) disposed in the hinge housing 310. According to an embodiment, the hinge housing 310 may be covered by a portion of the first housing 210 and the second housing 220 or may be exposed to the outside depending on whether the electronic device 200 is in the unfolded state, the folded state, or the intermediate state. For example, when the electronic device 200 is in the unfolded state, at least a portion of the hinge housing 310 may be covered by the first housing 210 and the second housing 220 and may be substantially unexposed. According to an embodiment, when the electronic device 200 is in the folded state, at least a portion of the hinge housing 310 may be exposed to the outside between the first housing 210 and the second housing 220. According to an embodiment, when the first housing 210 and the second housing 220 are in the intermediate state folded with a certain angle, the hinge housing 310 may be at least partially exposed to the outside of the electronic device 200 between the first housing 210 and the second housing 220. For example, the region of the hinge housing 310 exposed to the outside may be smaller than that in the case where the electronic device is fully folded. According to an embodiment, the hinge housing 310 may include a curved surface.

According to various embodiments, when the electronic device 200 is in the unfolded state (e.g., the state of FIGS. 2A and 2B), the first housing 210 and the second housing 220 may form an angle of about 180 degrees, and a first region 230a, a second region 230b, and a folding region 230c of the first display 230 may be arranged to be coplanar and oriented in substantially the same direction (e.g., the z-axis direction). In an embodiment, when the electronic device 200 is in the unfolded state, the first housing 210 may be rotated by about 360 degrees relative to the second housing 220 and folded in an opposite folding manner so as to make the second surface 212 and the fourth surface 222 face each other (an out-folding type).

According to various embodiments, when the electronic device 200 is in the folded state (e.g., the states of FIGS. 3A and 3B), the first surface 211 of the first housing 210 and the third surface 221 of the second housing 220 may be arranged to face each other. In this case, the first region 230a and the second region 230b of the first display 230 may form a narrow angle (e.g., in a range of 0 degrees to about 10 degrees) with each other via the folding region 230c, and may be arranged to face each other. According to an embodiment, at least a portion of the folding region 230c may be transformed into a curved shape with a predetermined curvature. According to an embodiment, when the electronic device 200 is in the intermediate state, the first housing 210 and the second housing 220 may be arranged at a certain angle with respect to each other. In this case, the first region 230a and the second region 230b of the first display 230 may form an angle greater than that in the folded state and smaller than that in the unfolded state, and the curvature of the folding region 230c may be smaller than that in the folded state and greater than that in the unfolded state. In various embodiments, the first housing 210 and the second housing 220 may form an angle that allows the electronic device 200 to stop at a predetermined folding angle between the folded state and the unfolded state through the hinge device (e.g., the hinge device 320 of FIG. 4) (free-stop function). In various embodiments, the first housing 210 and the second housing 220 may be continuously operated in an opening direction or a closing direction under pressure with reference to a predetermined inflection angle via a hinge device (e.g., the hinge device 320 of FIG. 4).

According to various embodiments, the electronic device 200 may include one or more of at least one display 230 or 300 disposed on the first housing 210 and/or the second housing 220, an input device 215, acoustic output devices 227 and 228, sensor modules 217a, 217b, and 226, camera modules 216a, 216b, and 225, key input devices 219, an indicator (not illustrated), or a connector port 229. In various embodiments, at least one of the components may be omitted from the electronic device 200 or at least one other component may be additionally included.

According to various embodiments, the at least one display 230 and 300 may include a first display 230 (e.g., a flexible display module) disposed to be supported by the first surface 211 of the first housing 210 and the third surface 221 of the second housing 220 across the hinge device (e.g., the hinge device 320 of FIG. 4), and a second display 300 disposed in an internal space of the second housing 220 to be at least partially visible from the outside through the fourth surface 222. In various embodiments, the second display 300 may be disposed in the internal space of the first housing 210 to be visible from the outside through the second surface 212. According to an embodiment, the first display 230 may be primarily used when the electronic device 200 is in the unfolded state, and the second display 300 may be primarily used when the electronic device 200 is in the folded state. According to an embodiment, when the electronic device 200 is in the intermediate state, the electronic device 200 may control the first display 230 and/or the second display 300 to be usable based on the folding angle between the first housing 210 and the second housing 220.

According to various embodiments, the first display 230 may be disposed in an accommodation space defined by the pair of housings 210 and 220. For example, the first display 230 may be disposed in the recess 201 defined by the pair of housings 210 and 220, and may be disposed to occupy substantially most of the front surface of the electronic device 200 in the unfolded state. According to an embodiment, the first display 230 may include a flexible display module having at least a portion that is deformable into a flat or curved surface. According to an embodiment, the first display 230 may include a first region 230a facing the first housing 210 and a second region 230b facing the second housing 220. According to an embodiment, the first display 230 may include a folding region 230c including a portion of the first region 230a and a portion of the second region 230b with respect to the folding axis A. According to an embodiment, at least a portion of the folding region 230c may include a region corresponding to the hinge device (e.g., the hinge device 320 of FIG. 4). According to an embodiment, the division of regions of the first display 230 is merely an example physical division defined by the pair of housings 210 and 220 and the hinge device (e.g., the hinge device 320 of FIG. 4), and the first display 230 may be displayed as a seamless, single full screen through the pair of housings 210 and 220 and the hinge device (e.g., the hinge device 320 of FIG. 4). According to an embodiment, the first region 230a and the second region 230b may have an overall symmetrical shape or a partially asymmetrical shape with respect to the folding region 230c.

According to various embodiments, the electronic device 200 may include a first rear surface cover 240 disposed on the second surface 212 of the first housing 210 and a second rear surface cover 250 disposed on the fourth surface 222 of the second housing 220. In various embodiments, at least a portion of the first rear surface cover 240 may be formed integrally with the first side surface member 213. In various embodiments, at least a portion of the second rear surface cover 250 may be formed integrally with the second side surface member 223.

According to various embodiments, the input device 215 may include a microphone. In various embodiments, the input devices 215 may include a plurality of microphones disposed to detect the direction of sound. According to an embodiment, the acoustic output devices 227 and 228 may include speakers. According to an embodiment, the acoustic output devices 227 and 228 may include a communication receiver 227 disposed through the fourth surface 222 of the second housing 220, and an external speaker 228 disposed through at least a portion of the second side surface member 223 of the second housing 220. In various embodiments, the input device 215, the acoustic output devices 227 and 228, and the connector 229 may be disposed in spaces of the first housing 210 and/or the second housing 220, and may be exposed to an external environment through at least one hole formed in the first housing 210 and/or the second housing 220.

According to various embodiments, the camera modules 216a, 216b, and 225 may include a first camera module 216a disposed on the first surface 211 of the first housing 210, a second camera module 216b disposed on the second surface 212 of the first housing 210, and/or a third camera module 225 disposed on the fourth surface 222 of the second housing 220. According to an embodiment, the electronic device 200 may include a flash 218 disposed near the second camera module 216b.

According to various embodiments, the sensor modules 217a, 217b, and 226 may generate electrical signals or data values corresponding to an internal operating state or an external environmental state of the electronic device 200. According to an embodiment, the sensor modules 217a, 217b, and 226 may include a first sensor module 217a disposed on the first surface 211 of the first housing 210, a second sensor module 217b disposed on the second surface 212 of the first housing 210, and/or a third sensor module 226 disposed on the fourth surface 222 of the second housing 220. In various embodiments, the sensor modules 217a, 217b, and 226 may include at least one of a gesture sensor, a grip sensor, a color sensor, an infrared (IR) sensor, an illuminance sensor, an ultrasonic sensor, an iris recognition sensor, or a distance detection sensor (e.g., a time-of-flight (TOF) sensor or a light detection and ranging (LiDAR)).

According to various embodiments, the key input device 219 may be disposed to be exposed to the outside through the first side surface member 213 of the first housing 210. In various embodiments, the key input device 219 may be disposed to be exposed to the outside through the second side surface member 223 of the second housing 220.

According to various embodiments, the connector port 229 may include a connector (e.g., a USB connector or an interface connector port module (IF module)) configured to transmit/receive power and/or data to and from an external electronic device.

According to various embodiments, at least one camera module 216a or 225 among the camera modules 216a, 216b, and 225, at least one sensor module 217a or 226 among the sensor modules 217a, 217b, and 226, and/or an indicator may be disposed to be exposed through the at least one display 230 or 300. For example, the at least one camera module 216a or 225, the at least one sensor module 217a or 226, and/or the indicator may be disposed in the internal space of the at least one housing 210 or 300 below the active region (display region) of the at least one display 230 or 300, and may be disposed to come into contact with the external environment through an opening perforated up to the cover member (e.g., a window layer (not illustrated) of the first display 230) and/or the second rear surface cover 250 or a transparent region.

FIG. 4 is an exploded perspective view of the electronic device 200 according to various embodiments.

Referring to FIG. 4, the electronic device 200 may include a first display 230 (e.g., a flexible display module), a second display 300, a hinge device 320, a pair of support members 261 and 262, at least one substrate 270 (e.g., a printed circuit board (PCB)), a first housing 210, a second housing 220, a first rear surface cover 240, and/or a second rear surface cover 250.

According to various embodiments, the first display 230 may include a display panel 430 (e.g., a flexible display panel), a support plate 450 disposed under the display panel 430, and a pair of reinforcement plates 461 and 462 disposed under the support plate 450. According to an embodiment, the display panel 430 may include a first panel region 430a corresponding to the first region of the first display 230 (e.g., the first region 230a of FIG. 2A), a second panel region 430b extending from the first panel region 430a and corresponding to the second region of the first display 230 (e.g., the second region 230b of FIG. 2A), and a third panel region 430c connecting the first panel region 430a and the second panel region 430b and corresponding to the folding region of the first display 230 (e.g., the folding region 230c of FIG. 2A). According to an embodiment, the support plate 450 may be disposed between the display panel 430 and a pair of support members 261 and 262 and may be configured to have a material and a shape to provide a flat support structure for the first panel region 430a and the second panel region 430b and a bendable structure for supporting bendability of the third panel region 430c. According to an embodiment, the support plate 450 may be formed of a conductive material (e.g., metal) or a non-conductive material (e.g., polymer or fiber reinforced plastics (FRP)). According to an embodiment, the pair of reinforcement plates 461 and 462 may include a first reinforcement plate 461 disposed between the support plate 450 and the pair of support members 261 and 262 to correspond to at least a portion of the first panel region 430a and the third panel region 430c, and a second reinforcement plate 462 corresponding to at least a portion of the second panel region 430b and the third panel region 430c. According to an embodiment, the pair of reinforcement plates 461 and 462 may be formed of a metal material (e.g., SUS), thereby contributing to a grounding connection structure and rigidity reinforcement for the first display 230.

According to various embodiments, the second display 300 may be disposed in a space between the second housing 220 and the second rear surface cover 250. According to an embodiment, the second display 300 may be disposed in the space between the second housing 220 and the second rear surface cover 250 such that the second display 300 is visible from the outside through substantially the entire area of the second rear surface cover 250.

According to various embodiments, at least a portion of the first support member 261 may be coupled to the second support member 262 to be foldable via the hinge device 320. According to an embodiment, the electronic device 200 may include at least one wiring member 263 (e.g., a flexible printed circuit board (FPCB)) extending from at least a portion of the first support member 261 to a portion of the second support member 262 across the hinge device 320. According to an embodiment, the first support member 261 may extend from the first side surface member 213 or may be disposed in a manner of being structurally coupled with the first side surface member 213. According to an embodiment, the electronic device 200 may include a first space (e.g., the first space 2101 in FIG. 2A) provided by the first support member 261 and the first rear surface cover 240.

According to an embodiment, the first housing 210 (e.g., a first housing structure) may be configured through coupling of the first side surface member 213, the first support member 261, and the first rear surface cover 240. According to an embodiment, the second support member 262 may extend from the second side surface member 223 or may be disposed in a manner of being structurally coupled with the second side surface member 223. According to an embodiment, the electronic device 200 may include a second space (e.g., the second space 2201 in FIG. 2A) provided by the second support member 262 and the second rear surface cover 250.

According to an embodiment, the second housing 220 (e.g., a second housing structure) may be configured through coupling of the second side surface member 223, the second support member 262, and the second rear surface cover 250. According to an embodiment, at least a portion of at least one wiring member 263 and/or the hinge device 320 may be disposed to be supported by at least a portion of the pair of support members 261 and 262. According to an embodiment, the at least one wiring member 263 may be arranged in a direction crossing the first support member 261 and the second support member 262 (e.g., in the x-axis direction). According to an embodiment, the at least one wiring member 263 may be disposed in a direction (e.g., the x-axis direction) substantially perpendicular to the folding axis (e.g., the y-axis or the folding axis A of FIG. 2A).

According to various embodiments, the at least one board 270 may include a first board 271 disposed in the first space 2101 and a second board 272 disposed in the second space 2201. According to an embodiment, the first board 271 and the second board 272 may include a plurality of electronic components disposed thereon to implement various functions of the electronic device 200. According to an embodiment, the first substrate 271 and the second substrate 272 may be electrically connected to each other via the at least one wiring member 263.

According to various embodiments, the electronic device 200 may include one or more batteries 291 or 292. According to an embodiment, the one or more batteries 291 or 292 may include a first battery 291 disposed in the first space 2101 of the first housing 210 and electrically connected to the first substrate 271, and a second battery 292 disposed in the second space 2201 of the second housing 220 and electrically connected to the second substrate 272.

According to various embodiments, the first housing 210 may include a first rotational support surface 214, and the second housing 220 may include a second rotational support surface 224 corresponding to the first rotational support surface 214. According to an embodiment, the first rotational support surface 214 and the second rotational support surface 224 may each include a curved surface corresponding to (smoothly connected to) the curved outer surface of the hinge housing 310. According to an embodiment, when the electronic device 200 is in the unfolded state, the first rotational support surface 214 and the second rotational support surface 224 may cover the hinge housing 310 so that the hinge housing 310 is not exposed or is only partially exposed to the rear surface of the electronic device 200. According to an embodiment, when the electronic device 200 is in the folded state, the first rotational support surface 214 and the second rotational support surface 224 may rotate along the curved outer surface of the hinge housing 310 to expose at least a portion of the hinge housing 310 to the rear surface of the electronic device 200.

According to various embodiments, the electronic device 200 may include at least one antenna 276 disposed in the first space 2201. According to an embodiment, the at least one antenna 276 may be disposed between the first battery 291 and the first rear surface cover 240 in the first space 2201. According to an embodiment, the at least one antenna 276 may include, for example, a near field communication (NFC) antenna, a wireless charging antenna, and/or a magnetic secure transmission (MST) antenna. According to an embodiment, the at least one antenna 276 may perform, for example, near field communication with an external device or wireless transmission/reception of power required for charging. In various embodiments, an antenna structure may be formed by at least a portion of the first side surface member 213 or the second side surface member 223, and/or a portion or a combination of the first support member 261 and the second support member 262.

According to various embodiments, the electronic device 200 may further include at least one electronic component assembly 274 or 275 and/or additional support members 263 disposed in the first space 2101 and/or the second space 2201. For example, the at least one electronic component assembly may include an interface connector port assembly 274 or a speaker assembly 275.

According to various embodiments, the electronic device 200 may include a first waterproof structure WP1 disposed between the first reinforcement plate 461 and the first support member 261, and a second waterproof structure WP2 disposed between the second reinforcement plate 462 and the second support member 262. According to an embodiment, the first waterproof structure WP1 may include a first waterproof member 481 disposed between the first reinforcement plate 461 and the first support member 261 so as to define at least one first waterproof space 4811, 4812, or 4813. According to an embodiment, the second waterproof structure WP2 may include a second waterproof member 482, a third waterproof member 483, and a fourth waterproof member 484 disposed between the second reinforcement plate 462 and the second support member 262 so as to define at least one second waterproof space 4821. According to an embodiment, the fourth waterproof member 484 may be disposed to connect stepped and spaced-apart spaces in the second waterproof member 482 and the third waterproof member 483.

According to various embodiments, the electronic device 200 may include a waterproof tape 241 disposed between the first rear surface cover 240 and the first housing 210. According to an embodiment, the electronic device 200 may include a bonding member 251 disposed between the second rear surface cover 250 and the second housing 220. In various embodiments, the bonding member 251 may be disposed between the second display 300 and the second housing 220. In various embodiments, the waterproof tape 241 may be replaced with the bonding member 251, and the bonding member 251 may be replaced with the waterproof tape 241.

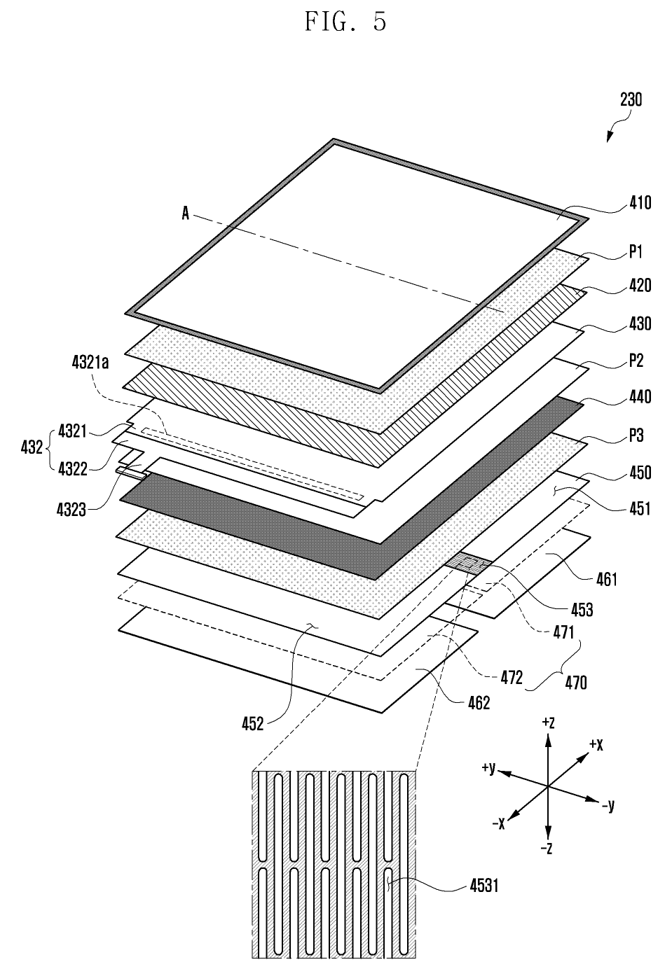

FIG. 5 is an exploded perspective view of a display module 230 according to various embodiments. The display module illustrated in FIG. 5 may be an example of the first display (e.g., the first display 230 of FIGS. 2A and 4) described above with reference to FIGS. 2A and 4.

The flexible display module 230 according to various example embodiments of the disclosure may include an unbreakable (UB)-type OLED display (e.g., a curved display). However, the disclosure is not limited thereto, and the flexible display module 230 may include a flat-type display of an on-cell-touch active-matrix organic light-emitting diode (AMOLED) (OCTA) type. In the disclosure, the term “flexible display module 230” may be used interchangeably with “display module 230.”

Referring to FIG. 5, the flexible display module 230 may include a window layer 410, and a polarizer (POL) 420 (e.g., a polarizing film), a display panel 430, a polymer layer 440, a support plate 450, and reinforcement plates 461 and 462 sequentially disposed on a rear surface of the window layer 410 (e.g., in the -z-axis direction). In various embodiments, the flexible display module 230 may include a digitizer panel 470 disposed between the support plate 450 and the reinforcement plates 461 and 462. In various embodiments, the digitizer panel 470 may be disposed between the polymer layer 440 and the support plate 450.

According to various embodiments, the window layer 410 may include a glass layer. According to an embodiment, the window layer 410 may include ultra-thin glass (UTG). In various embodiments, the window layer 410 may include a polymer. In this case, the window layer 410 may include polyethylene terephthalate (PET) or polyimide (PI). In various embodiments, the window layer 410 may be arranged in a plurality of layers to include a glass layer and a polymer.

According to various embodiments, the window layer 410, the polarizer 420, the display panel 430, the polymer layer 440, and the support plate 450 may be arranged to extend across at least a portion of the first surface (e.g., the first surface 211 of FIG. 2A) of the first housing (e.g., the first housing 210 of FIG. 2A) and the third surface (e.g., the third surface 221 of FIG. 2A) of the second housing (e.g., the second housing 220 of FIG. 2A). According to an embodiment, the reinforcement plates 461 and 462 may include a first reinforcement plate 461 corresponding to the first housing (e.g., the first housing 210 of FIG. 2A) and a second reinforcement plate 462 corresponding to the second housing (e.g., the second housing 220 of FIG. 2A). According to an embodiment, the reinforcement plates 461 and 462 may provide rigidity for the flexible display module 230 and may serve as a ground for preventing and/or reducing malfunction of the flexible display module 230. According to an embodiment, the reinforcement plates 461 and 462 may be formed of a metal material. According to an embodiment, the reinforcement plates 461 and 462 may be formed of SUS or AL. According to an embodiment, the window layer 410, the polarizer 420, the display panel 430, the polymer layer 440, the support plate 450, and the reinforcement plates 461 and 462 may be attached to each other using adhesives P1, P2, and P3 (or an adhesive). For example, the adhesives P1, P2, and P3 may include at least one of an optical clear adhesive (OCA), a pressure-sensitive adhesive (PSA), a heat-responsive adhesive, a general adhesive, or double-sided tape.

According to various embodiments, the display panel 430 may include multiple pixels and a wiring structure (e.g., an electrode pattern). According to an embodiment, the polarizer 420 may selectively make light, which is generated from a light source of the display panel 430 and vibrates in a predetermined direction, pass therethrough. According to an embodiment, the display panel 430 and the polarizer 420 may be integrally configured. According to an embodiment, the flexible display module 230 may further include a touch panel (not illustrated).

According to various embodiments, the polymer layer 440 may be disposed under the display panel 430 to provide a dark background for ensuring visibility of the display panel 430, and may be made of a buffering material for a buffering action. In various embodiments, for waterproofing of the flexible display module 230, the polymer layer 440 may be removed or disposed under the support plate 450.

According to various embodiments, the support plate 450 may provide a bendable property to the flexible display module 230. For example, the support plate 450 may be made of a non-metallic sheet material, such as fiber-reinforced plastics (FRP) (e.g., carbon fiber-reinforced plastics (CFRP) or glass fiber-reinforced plastics (GFRP)), having a rigid property to support the display panel 430. According to an embodiment, the support plate 450 may include a first flat portion 451 corresponding to the first housing (e.g., the first housing 210 of FIG. 2A), a second flat portion 452 corresponding to the second housing (e.g., the second housing 220 of FIG. 2A), and a bending portion 453 connecting the first flat portion 451 and the second flat portion 452. According to an embodiment, the bending portion 453 may include a plurality of openings 4531 arranged at specified intervals. According to an embodiment, the bending characteristics of the bending portion 453 may be determined by at least one of the size, shape, or arrangement density of at least some of the plurality of openings 4531. In various embodiments, the support plate 450 may be made of a metal material such as steel use stainless (SUS) (e.g., stainless steel (STS)), Cu, Al, or a metal CLAD (e.g., a laminated member in which SUS and Al are alternately disposed). In this case, throughout the entire region of the support plate 450, the multiple openings may be formed to induce the detection operation of the digitizer panel 470 disposed below the support plate. According to an embodiment, the support plate 450 may contribute to reinforcing the rigidity of the electronic device (e.g., the electronic device 200 of FIG. 2A), may shield surrounding noise, and may be used to disperse heat emitted from surrounding heat-dissipating components.

According to various embodiments, the display module 230 (e.g., the first display 230 of FIG. 2A) may include a digitizer panel 470 disposed under the support plate 450 as a detection member configured to receive an input from an electronic pen (e.g., a stylus). According to an embodiment, the digitizer panel 470 may include coil members disposed on a dielectric substrate (e.g., a dielectric film or a dielectric sheet) so as to detect an electromagnetic induction-type resonance frequency applied from the electronic pen. According to an embodiment, the digitizer panel 470 may include a first digitizer panel 471 corresponding to the first housing (e.g., the first housing 210 of FIG. 2A) and a second digitizer panel 472 corresponding to the second housing (e.g., the second housing 220 of FIG. 2A). According to an embodiment, the first digitizer panel 471 and the second digitizer panel 472 may each be electrically connected to substrates (e.g., the substrates 271 and 272 of FIG. 4) of the electronic device (e.g., the electronic device 200 of FIG. 4) using FPCB connectors, and may operate as a single digitizer panel. In various embodiments, the first digitizer panel 471 and the second digitizer panel 472 may be operated separately.

According to various embodiments, the flexible display module 230 may include one or more functional members (not illustrated) disposed between the polymer layer 440 and the support plate 450 or below the support plate 450. According to an embodiment, the functional member may include a graphite sheet for heat dissipation, an added display, a force touch FPCB, a fingerprint sensor FPCB, a communication antenna radiator, or a conductive/non-conductive tape. According to an embodiment, when the functional member is not bendable, it may be individually disposed in the first housing (e.g., the first housing 210 of FIG. 2A) and the second housing (e.g., the second housing 220 of FIG. 2A). According to an embodiment, when the functional member is bendable, it may be disposed from the first housing (e.g., the first housing 210 of FIG. 2A) to at least a portion of the second housing (e.g., the second housing 220 of FIG. 2A) through the hinge device (e.g., the hinge device 320 of FIG. 4).

According to various embodiments, the flexible display module 230 may include a bending region 432 disposed to be folded from the display panel 430 toward at least a portion of a rear surface of the flexible display module 230 (e.g., in the -z-axis direction). According to an embodiment, the bending region 432 may include an extension 4321 extending from the display panel 430 and including a control circuit 4321a, and a flexible substrate 4322 electrically connected to the extension 4321 and including a plurality of electrical elements. According to an embodiment, the control circuit 4321a may include a display driver IC (DDI) or a touch and display driver IC (TDDI) disposed on the extension 4321 having an electrical wiring structure.

According to an embodiment, the flexible display module 230 may include an FPCB connector 4323 extending from the flexible substrate 4322 and electrically connected to a substrate (e.g., the second substrate 272 of FIG. 4) of the electronic device (e.g., the electronic device 200 of FIG. 4).

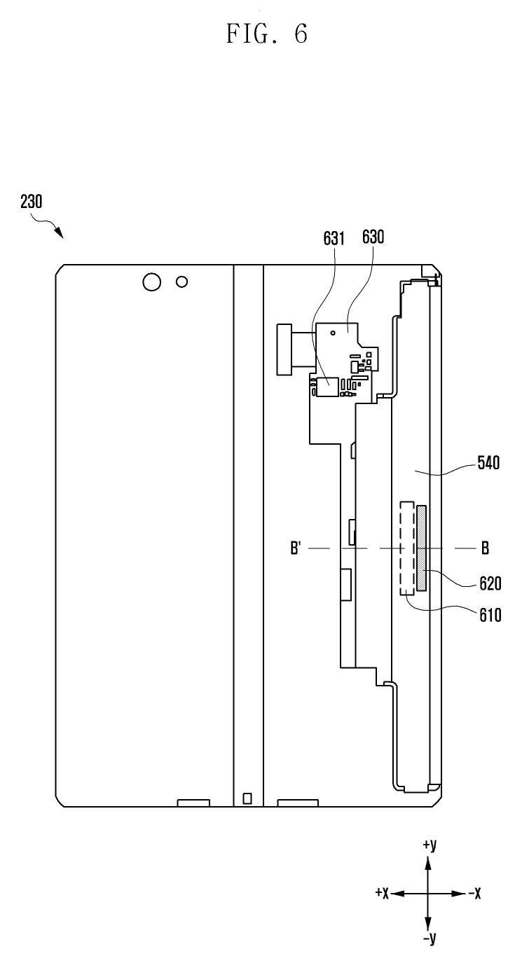

FIG. 6 is a diagram illustrating a rear view of a configuration of a display module 230 according to a comparative example.

Referring to FIG. 6, the display module 230 of the electronic device according to the comparative example may be at least partially similar to the flexible display module 230 described with reference to FIGS. 2A-5.

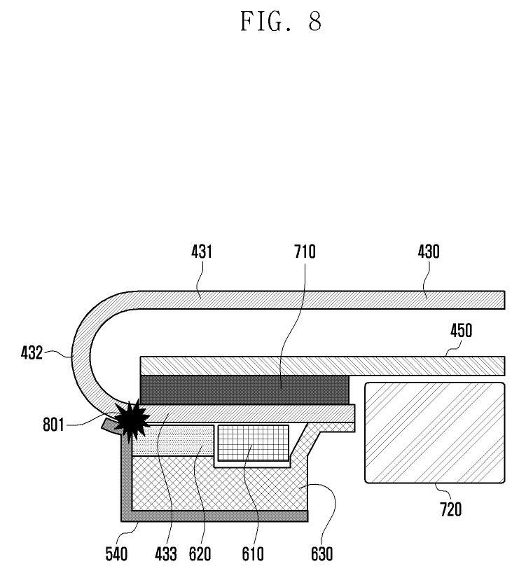

In the comparative example, on the display module 230, a bending region 432 (e.g., 432 of FIG. 5) and an extension region 433 (e.g., 4321 of FIG. 5) of the display panel 430 may be disposed when viewed from a rear side of the display module 230. A display driving circuit (hereinafter, referred to as a display driver IC (DDI) 610) (e.g., the control circuit 4321a of FIG. 5) may be disposed in the extension region 433 of the display module 230, and the DDI 610 may be covered by an FPCB 630 bonded in a reverse direction with respect to the display panel 430. Accordingly, when viewed from the rear side of the display module 230, the DDI 610 may be substantially invisible, and only the FPCB 630 may be visible. The comparative example may further include a cover member 540 (e.g., 540 of FIG. 8) covering the FPCB 630. The cover member 540 may include at least one conductive layer and at least one non-conductive layer, and an outermost layer of the cover member 540 may be formed of a non-conductive layer.

In the comparative example, the rear surface of the display module 230 may be a surface disposed to face the rear side of the electronic device 200 when the electronic device 200 is in the unfolded state. The rear surface of the display module 230 may refer to a surface facing the rear surface cover (e.g., 240 or 250 in FIG. 4) of the electronic device 200.

In the comparative example, the display module 230 may have a waterproof tape 620, which may be attached around the DDI 610 to prevent and/or reduce external static electricity from flowing into the DDI 610. In the comparative example, the waterproof tape 620 may be attached in a first direction (e.g., the -x direction in FIG. 6) from the DDI 610 where the bending region 432 is positioned. The waterproof tape 620 may serve to attach an end portion of the FPCB 630 to the display panel 430 and to prevent and/or reduce static electricity introduced from the outside through the bending region 432 from flowing into the DDI 610.

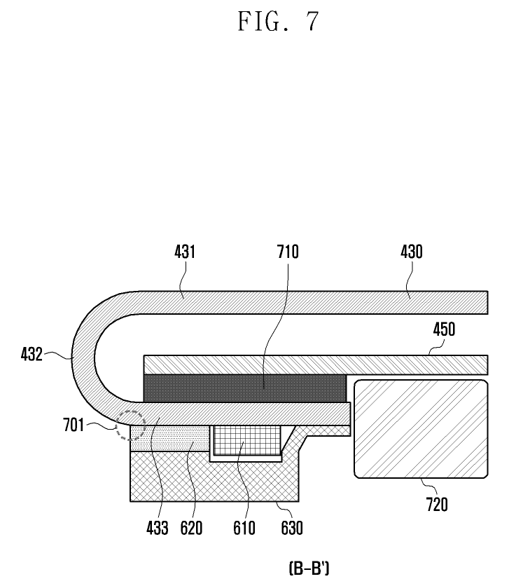

FIG. 7 is a partial cross-sectional view of an electronic device schematically illustrating an edge of the display module 230 according to the comparative example illustrated in FIG. 6. For example, FIG. 7 may be a cross-sectional view of an edge of the display module 230 illustrated in FIG. 6 taken along line B-B’.

Referring to FIG. 7, the display module 230 according to the comparative example includes a display panel 430 configured to be bendable. The display panel 430 may include a display region 431 configured to form a front surface of the display module 230 and to display an image, a bending region 432 extending from one end of the display region 431 and configured to be at least partially bent, and an extension region 433 extending from the bending region 432 toward a rear surface of the display module 230. The extension region 433 may be arranged substantially parallel to the display region 431. The extension region 433 may be used interchangeably with similar terms such as “extension” or “third region.”

According to the comparative example, a support plate 450 may be disposed below the display region 431 of the display panel 430, and the support plate 450 may be positioned between the display region 431 and the extension region 433 of the display panel 430. According to the comparative example, the display module 230 may include a spacer member 710 configured to compensate for a height difference between the display region 431 and the extension region 433. The spacer member 710 is disposed between the extension region 433 of the display panel 430 and the support plate 450 and serves to compensate for the height difference between the display region 431 and the extension region 433. The spacer member 710 may include a polymer material.

According to the comparative example, a DDI 610 may be disposed in the extension region 433. An FPCB 630 may be connected to one end of the extension region 433, and the FPCB 630 may be bonded to the display panel 430 in a reverse direction. The description that the FPCB 630 is bonded in a reverse direction may refer, for example, to the FPCB 630 extending, from one end (e.g., a pad region) bonded to the display panel 430, in a first direction (e.g., the -x direction in FIG. 6) in which the bending region 432 of the display panel 430 is located. When the FPCB 630 is bonded in the reverse direction, there is an advantage in that a larger space may be secured for placement of a battery 720 of the electronic device.

According to the comparative example, as the FPCB 630 extends in a first direction (e.g., the -x direction in FIG. 6) in which the bending region 432 is located, the FPCB 630 may cover the DDI 610, and an end portion of the FPCB 630 may be attached to a rear surface (e.g., a portion of the extension region 433) of the display panel 430 by the waterproof tape 620. In the comparative example, the waterproof tape 620 not only serves to attach the FPCB 630 to the display panel 430 but also serves to prevent and/or reduce static electricity introduced from the outside from flowing into the DDI 610. However, as denoted by reference numeral 701 in FIG. 7, the display module 230 according to the comparative example may experience lifting due to a reduction in adhesive force between the waterproof tape 620 and the display panel 430. When lifting of the waterproof tape 620 occurs, static electricity introduced from the outside may be transmitted to the DDI 610.

FIG. 8 is a partial cross-sectional view of an electronic device schematically illustrating an edge of the display module 230 according to the comparative example illustrated in FIG. 6. For example, FIG. 8 may be a cross-sectional view of an edge of the display module 230 illustrated in FIG. 6 taken along line B-B’.

The comparative example illustrated in FIG. 8 differs from that illustrated in FIG. 7 in that it further includes a cover member 540. Referring to FIG. 8, the display module 230 according to the comparative example may further include a cover member 540 that covers the FPCB 630 and the waterproof tape 620. Since the cover member 540 includes a non-conductive layer, it may protect the DDI 610 from static electricity. However, due to a height difference caused by the FPCB 630, an end portion of the cover member 540 may easily lift (801) from the surface of the display panel 430. When lifting (801) of the cover member 540 and the waterproof tape 620 occurs, static electricity introduced from the outside may be transmitted to the DDI 610.

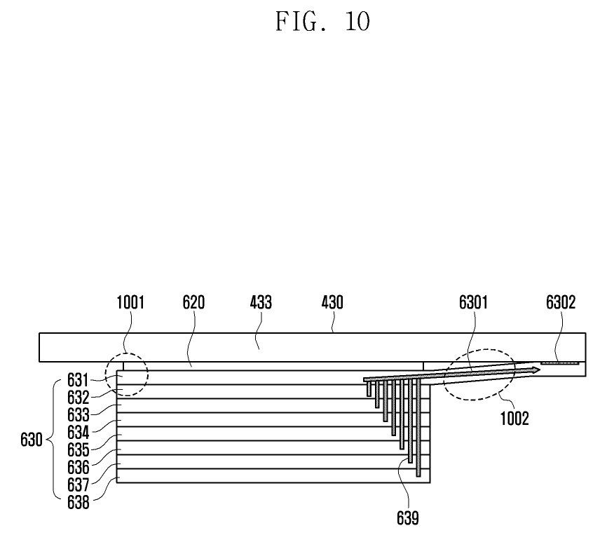

An embodiment of the disclosure includes a protective structure configured to prevent and/or reduce static electricity introduced from the outside from being transmitted to the DDI 610, even when lifting (801) of the waterproof tape 620 described with reference to FIGS. 7 and 8 occurs. Hereinafter, with reference to FIGS. 10 - 21, a protective structure configured to prevent and/or reduce static electricity introduced from the outside from being transmitted to the DDI 610 will be described in detail.

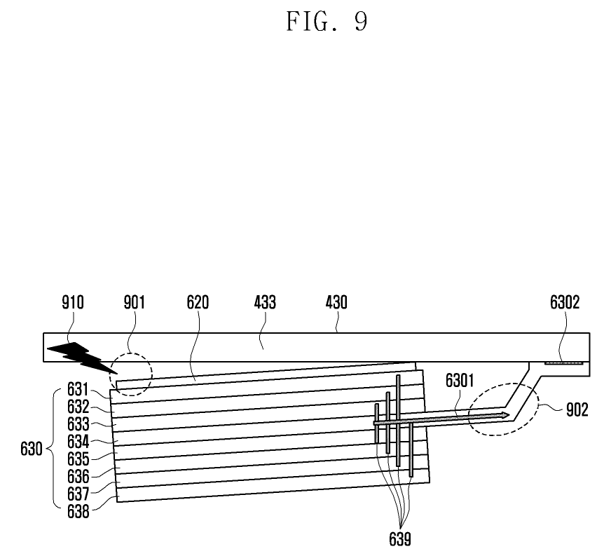

FIG. 9 is a diagram illustrating a wiring structure of the FPCB 630 and a lifting phenomenon of the waterproof tape 620 according to a comparative example. For example, FIG. 9 is a view illustrating the wiring structure of the FPCB 630 according to the comparative example illustrated in FIGS. 7 and 8, and illustrates a form of the FPCB 630 in which lifting of the waterproof tape 620 may easily occur.

Referring to FIG. 9, the FPCB 630 includes a multilayer structure including a plurality of wires. For example, the FPCB 630 may include, as outer layers, coverlay layers (not illustrated), and, as inner layers, a plurality of metal layers 631, 632, 633, 634, 635, 636, 637, and 638. The plurality of metal layers 631, 632, 633, 634, 635, 636, 637, and 638 include a first metal layer 631, a second metal layer 632, a third metal layer 633, a fourth metal layer 634, a fifth metal layer 635, a sixth metal layer 636, a seventh metal layer 637, and an eighth metal layer 638, which may be sequentially stacked. The first metal layer 631 is the uppermost layer among the metal layers (e.g., the metal layer closest to the waterproof tape 620), and the eighth metal layer 638 is the lowermost layer among the metal layers.

According to the comparative example, at least one wire (not illustrated) configured to transmit a plurality of signals and/or voltages for driving the display panel 430 may be disposed in each of the plurality of metal layers 631, 632, 633, 634, 635, 636, 637, and 638. The wires disposed in the respective metal layers 631, 632, 633, 634, 635, 636, 637, and 638 may be electrically connected to connection wires 6301 of one intermediate layer (e.g., the fourth metal layer 634) among the plurality of metal layers 631, 632, 633, 634, 635, 636, 637, and 638 through vias 639, and thus may be electrically connected to a pad portion 6302 disposed at one end of the FPCB 630.

In this comparative example, a connection portion 902 between the connection wires 6301 and the pad portion 6302 extends from the connection wires 6301 of one intermediate layer (e.g., the fourth metal layer 634) among the plurality of metal layers 631, 632, 633, 634, 635, 636, 637, and 638. In this comparative example, lifting (901) of the waterproof tape 620 may easily occur due to a height difference between the intermediate layer (e.g., the fourth metal layer 634) and the first metal layer 631, which is disposed closest to the coverlay to which the waterproof tape 620 is attached. When lifting (901) of the waterproof tape 620 occurs, static electricity 900 may flow into a gap between the display panel 430 (e.g., the extension region 433) and the FPCB 630, thereby damaging the DDI 610.

FIG. 10 is a diagram illustrating an example wiring structure of the FPCB 630, configured to reduce a lifting phenomenon of the waterproof tape 620 according to various embodiments. For example, the FPCB 630 illustrated in FIG. 10 has a form that differs from the wiring structure of the FPCB 630 according to the comparative example illustrated in FIG. 9 in that lifting of the waterproof tape 620 may be reduced.

Referring to FIG. 10, the FPCB 630 according to an embodiment includes a multilayer structure including a plurality of wires. For example, the FPCB 630 may include, as outer layers, coverlay layers (not illustrated), and, as inner layers, a plurality of metal layers 631, 632, 633, 634, 635, 636, 637, and 638. The plurality of metal layers 631, 632, 633, 634, 635, 636, 637, and 638 include a first metal layer 631, a second metal layer 632, a third metal layer 633, a fourth metal layer 634, a fifth metal layer 635, a sixth metal layer 636, a seventh metal layer 637, and an eighth metal layer 638, which may be sequentially stacked. The first metal layer 631 is the uppermost layer among the metal layers, and the eighth metal layer 638 is the lowermost layer among the metal layers.

According to an embodiment, at least one wire (not illustrated) configured to transmit a plurality of signals and/or voltages for driving the display panel 430 may be disposed in each of the plurality of metal layers 631, 632, 633, 634, 635, 636, 637, and 638. The wires disposed in the respective metal layers 631, 632, 633, 634, 635, 636, 637, and 638 may be electrically connected to connection wires 6301 of the uppermost layer (e.g., the first metal layer 631) among the plurality of metal layers 631, 632, 633, 634, 635, 636, 637, and 638 through vias 639, and thus may be electrically connected to a pad portion 6302 disposed at one end of the FPCB 630.

According to an embodiment, a connection portion 1002 between the connection wires 6301 and the pad portion 6302 extends from the connection wires 6301 of the uppermost layer (e.g., the first metal layer 631) among the plurality of metal layers 631, 632, 633, 634, 635, 636, 637, and 638. In this embodiment, unlike the comparative example of FIG. 9, a height difference between the coverlay to which the waterproof tape 620 is attached and the first metal layer 631 where the connection portion 1002 is disposed is reduced, so that lifting (1001) of the waterproof tape 620 may be reduced or prevented. When lifting (1001) of the waterproof tape 620 is reduced, an issue in which static electricity (e.g., 900 of FIG. 9) flows into a gap between the display panel 430 (e.g., the extension region 433) and the FPCB 630, thereby damaging the DDI 610, may also be reduced. According to an embodiment, an insulating layer may be provided between the plurality of metal layers 631, 632, 633, 634, 635, 636, 637, and 638. For example, an insulating layer may be disposed between the first metal layer 631 and the second metal layer 632. For example, the insulating layer may be formed of an insulating material. For example, the insulating layer may include an insulating film (e.g., polyester (polyethylene terephthalate; PET) or polyimide (PI)) or epoxy.

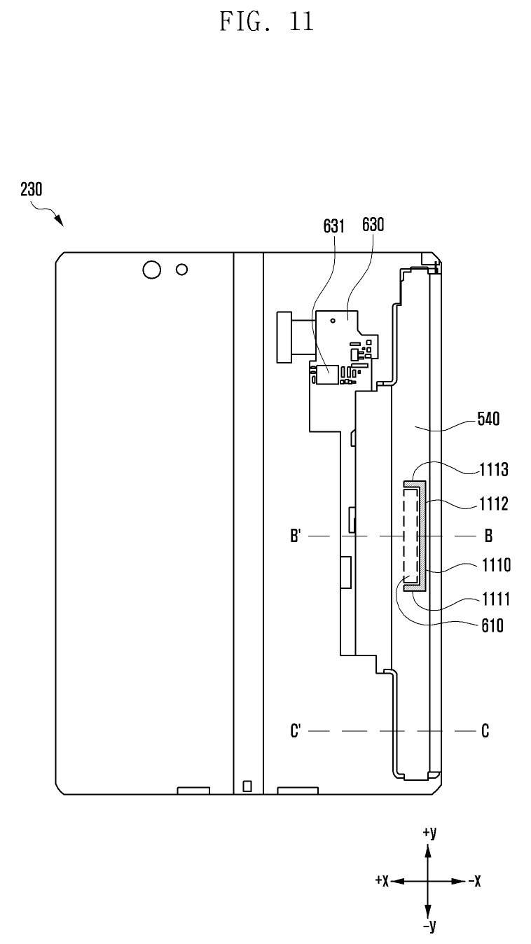

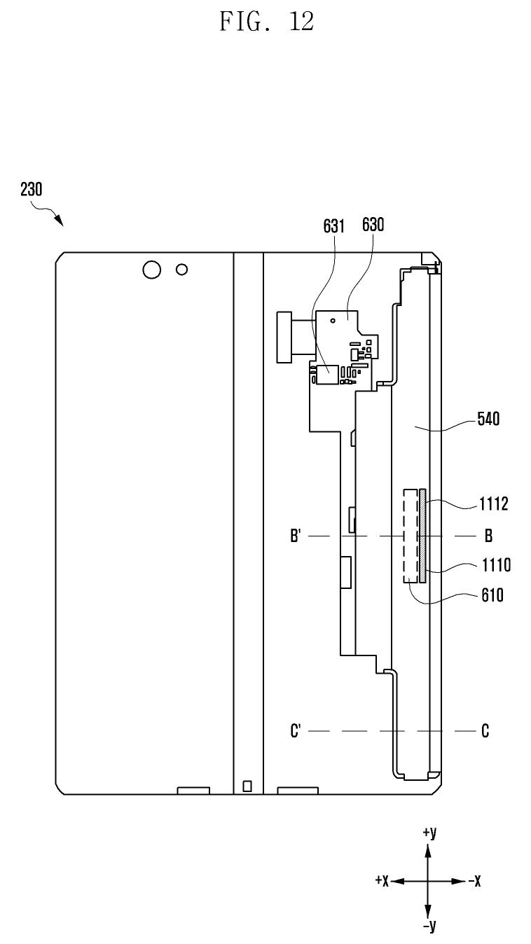

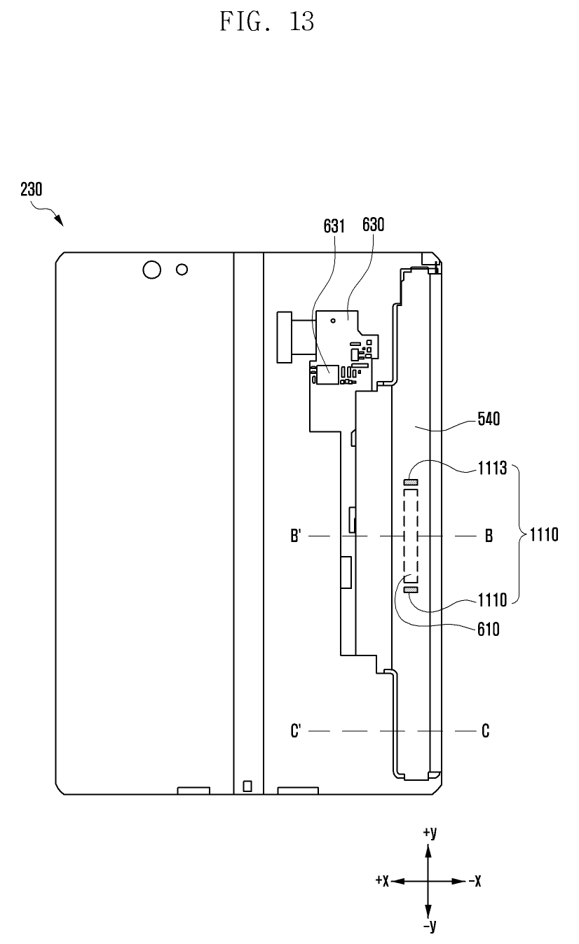

FIGS. 11, 12 and 13 are diagrams each illustrating an example configuration of a rear surface of a display module 230 according to various embodiments. For example, FIG. 11 illustrates an example in which an FPCB 630 according to an embodiment includes a slit forming a discharge path for static electricity introduced into the FPCB 630, the slit being arranged to correspond to three sides of the DDI 610. For example, FIG. 12 illustrates an example in which an FPCB 630 according to an embodiment includes a slit forming a discharge path for static electricity introduced into the FPCB 630, the slit being arranged to correspond to one side of the DDI 610. For example, FIG. 13 illustrates an example in which an FPCB 630 according to an embodiment includes a slit forming a discharge path for static electricity introduced into the FPCB 630, the slit being arranged to correspond to one side of the DDI 610.

The display modules 230 according to examples illustrated in FIGS. 11-13 may be at least partially similar to the comparative example described with reference to FIG. 6. Hereinafter, various embodiments of the disclosure that differ from the comparative example of FIG. 6 will be described.

Referring to FIG. 11, the FPCB 630 according to an embodiment includes a slit 1110 forming a discharge path for static electricity introduced into the FPCB 630, and the slit 1110 may be arranged to correspond to three sides of the DDI 610. According to an embodiment, the FPCB 630 may be disposed to cover the DDI 610 and may include at least one slit 1110 disposed adjacent to the DDI 610. According to an embodiment, the at least one slit 1110 may include a first portion 1112 disposed in a first direction (the -x direction) in which the bending region 432 is located from the DDI 610, a second portion 1113 disposed in a second direction (the y direction) perpendicular to the first direction from the DDI 610, and a third portion 1111 disposed in a third direction (the -y direction) opposite to the second direction (the y direction) from the DDI 610.

Referring to FIG. 12, the FPCB 630 according to an embodiment includes a slit 1110 forming a discharge path for static electricity introduced into the FPCB 630, and the slit 1110 may be arranged to correspond to one sides of the DDI 610. According to an embodiment, the FPCB 630 may be disposed to cover the DDI 610 and may include at least one slit 1110 disposed adjacent to the DDI 610. According to an embodiment, the slit 1110 may include a first portion 1112 disposed in a first direction (the -x direction) in which the bending region 432 is located from the DDI 610.

Referring to FIG. 13, the FPCB 630 according to an embodiment includes a slit 1110 forming a discharge path for static electricity introduced into the FPCB 630, and the slit 1110 may be arranged to correspond to two sides of the DDI 610. According to an embodiment, the FPCB 630 may be disposed to cover the DDI 610 and may include a slit 1110 disposed adjacent to the DDI 610. According to an embodiment, the slit 1110 may include a second portion 1113 disposed in a second direction (the y direction) perpendicular to the first direction from the DDI 610, and a third portion 1111 disposed in a third direction (the -y direction) opposite to the second direction from the DDI 610. According to an embodiment, the slit 1110 may include at least one of the second portion 1113 and the third portion 1111.

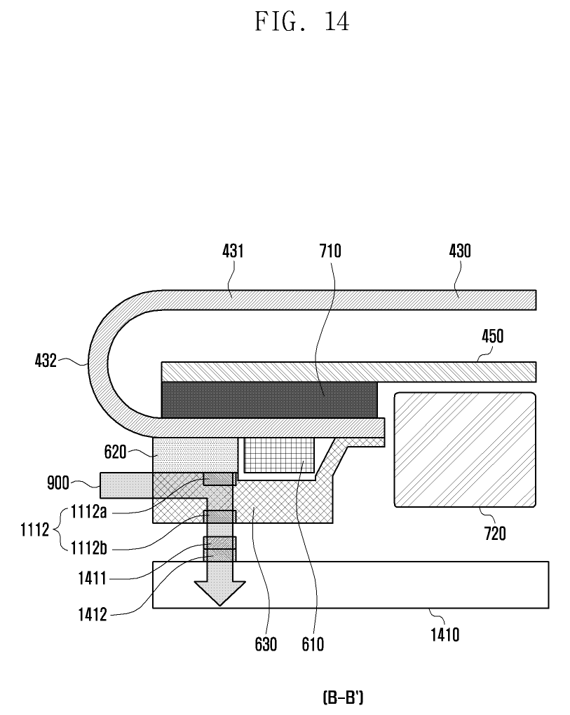

FIG. 14 is a partial cross-sectional view illustrating an example in which slits forming a discharge path for static electricity introduced into an FPCB 630 are disposed in a plurality of layers according to various embodiments. For example, FIG. 14 illustrates a cross-sectional view of the display module 230 taken along line B-B’ of FIGS. 11 - 12 .

Referring to FIG. 14, the FPCB 630 may include a first cover layer (not illustrated) (e.g., a first coverlay) forming a first surface facing a DDI 610, a second cover layer (not illustrated) (e.g., a second coverlay) forming a second surface (e.g., a lower surface) opposite to the first surface (e.g., an upper surface), and one or more metal layers (e.g., 631, 632, 633, 634, 635, 636, 637, and 638 of FIG. 10) disposed between the first cover layer and the second cover layer.

According to an embodiment, the first cover layer of the FPCB 630 may include at least one first slit 1112a (e.g., the slit 1110 of FIG. 11) disposed adjacent to the DDI 610 and exposing a portion of at least one metal layer. According to an embodiment, the at least one first slit 1112a may be disposed to face the waterproof tape 620. The first slit 1112a may form a discharge path 910 through which static electricity introduced from the outside flows, even when lifting of the waterproof tape 620 occurs. The static electricity introduced through the first slit 1112a may be discharged to a ground of the FPCB 630 or, as described later, discharged to a shielding component 1412 (e.g., a gasket) disposed on a support member 1410.

According to an embodiment, the second cover layer of the FPCB 630 may further include at least one second slit 1112b. The at least one second slit 1112b may be disposed so as to at least partially overlap the first slit 1112a. For example, static electricity introduced through the first slit 1112a may be discharged, through the second slit 1112b, to the support member disposed to face a rear surface of the FPCB 630. Here, the support member 1410 may be one of the pair of support members 261 and 262 described with reference to FIG. 4. The support member 1410 may include a shielding component 1412 (e.g., a gasket) and a conductive tape 1411, which are disposed to face the second slit 1112b. Static electricity introduced through the first slit 1112a may be discharged, through the second slit 1112b, to the shielding component 1412 (e.g., a gasket) disposed on the support member 1410 facing the rear surface of the FPCB 630. According to an embodiment, the cover layers (e.g., the first cover layer and the second cover layer) of the FPCB 630 may be formed of an insulating material. For example, the cover layers (e.g., the first cover layer and the second cover layer) of the FPCB 630 may include an insulating film (e.g., polyester (polyethylene terephthalate; PET) or polyimide (PI)) and/or an insulating coating (e.g., acrylic, silicone, urethane, epoxy, or parylene).

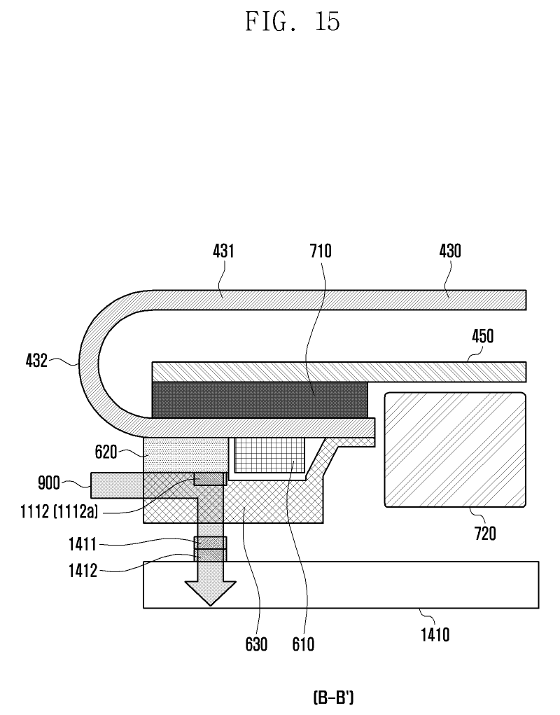

FIG. 15 is a partial cross-sectional view illustrating an example in which slits forming a discharge path for static electricity introduced into an FPCB 630 are disposed in a single layer according to various embodiments. For example, FIG. 15 illustrates a cross-sectional view of the display module 230 taken along line B-B’ of FIGS. 11 - 12 .

FIG. 15 may be at least partially similar to FIG. 14. Hereinafter, for FIG. 15, the differences from FIG. 14 will be described. Accordingly, features not described with reference to FIG. 15 will be replaced with the description of FIG. 14.

FIG. 15 may not include the second slit 1112b of the second cover layer of the FPCB 630.

According to an embodiment, the first cover layer of the FPCB 630 may include at least one first slit 1112a disposed adjacent to the DDI 610 and exposing a portion of at least one metal layer. According to an embodiment, the at least one first slit 1112a may be disposed to face the waterproof tape 620. The first slit 1112a may form a discharge path through which static electricity introduced from the outside flows, even when lifting of the waterproof tape 620 occurs. The static electricity introduced through the first slit 1112a may be discharged to a ground of the FPCB 630 or discharged to a shielding component (e.g., a gasket) disposed on a support member 1410.

According to an embodiment, the support member 1410 may include a shielding component (e.g., a gasket) and a conductive tape, which are disposed to overlap the first slit 1112a. Static electricity introduced through the first slit 1112a may be discharged to the shielding component (e.g., a gasket) disposed on the support member 1410.

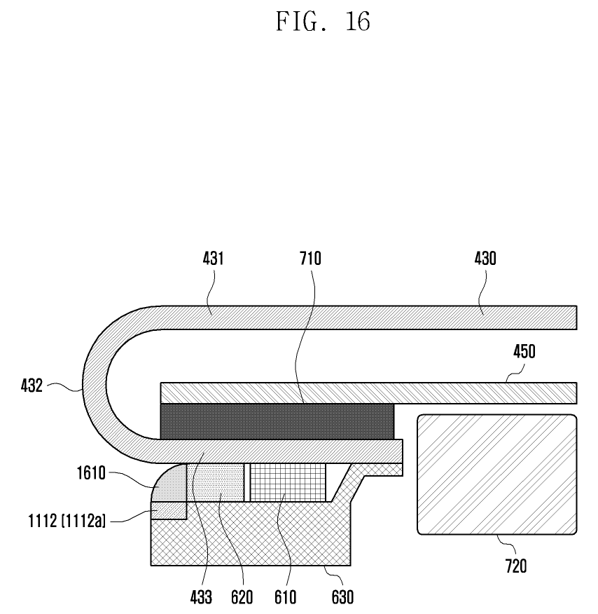

FIG. 16 is a partial cross-sectional view illustrating an example in which an FPCB 630 includes a slit forming a discharge path for static electricity introduced into the FPCB 630, and in which a display module 230 is disposed to face the slit and further includes a conductive member disposed at an outer edge of a waterproof tape 620 according to various embodiments. For example, FIG. 16 illustrates a cross-sectional view of the display module 230 taken along line B-B’ of FIGS. 11 - 12 .

FIG. 16 may be at least partially similar to FIG. 15. Hereinafter, for FIG. 16, the differences from FIG. 15 will be described. Accordingly, features not described with reference to FIG. 16 will be replaced with the description of FIG. 15.

FIG. 16 differs from FIG. 15 in that a conductive member 1610 is further disposed at an outer edge of the waterproof tape 620.

According to an embodiment, the display module 230 may further include a conductive member 1610 disposed adjacent to the waterproof tape 620. The conductive member 1610 may be formed of a conductive material or a coating member including a conductive substance.

According to an embodiment, the conductive member 1610 may be disposed in a first direction in which the bending region 432 is located from the waterproof tape 620. For example, when the conductive member 1610 is made of a conductive material, the conductive material may be designed to be attached to both the display panel 430 and the FPCB 630. According to an embodiment, since there is limited space outside the waterproof tape 620, the coating region of the conductive material or conductive substance may be designed to be narrower than the width of the waterproof tape 620.

According to an embodiment, the FPCB 630 may include at least one first slit 1112a disposed to face the conductive member 1610. The first slit 1112a may form a discharge path for discharging static electricity introduced from the conductive member 1610 or the waterproof tape 620 to a ground of the FPCB 630, or to a shielding component (e.g., 1412 of FIG. 14) (e.g., a gasket) disposed on a support member (e.g., 1410 of FIG. 14).

According to an embodiment, preferably, the conductive member 1610 may have a length sufficient to cover the entire length of the DDI 610. For example, the length of the conductive member 1610 may be designed to be greater than the length of the DDI 610. The illustrated embodiment may prevent and/or reduce the DDI 610 from being damaged by static electricity, even when lifting of the waterproof tape 620 occurs, by separately attaching the conductive member 1610.

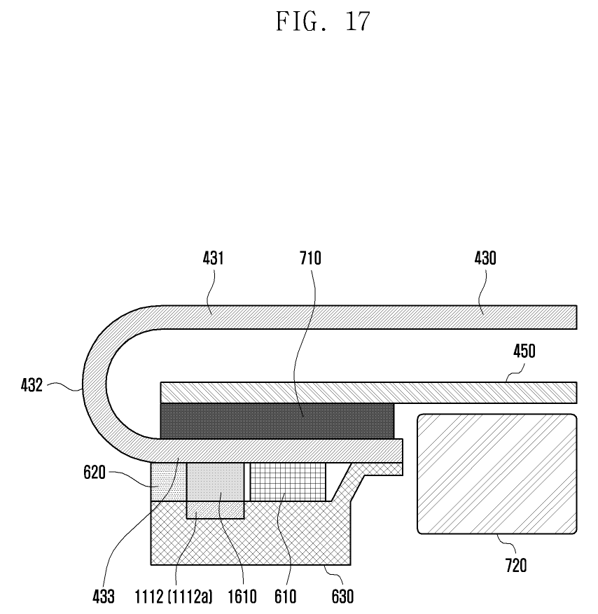

FIG. 17 is a partial cross-sectional view illustrating an example in which an FPCB 630 includes a slit forming a discharge path for static electricity introduced into the FPCB 630, and in which a display module 230 is disposed to face the slit and further includes a conductive member 1610 disposed between a waterproof tape 620 and a DDI 610 according to various embodiments. For example, FIG. 17 illustrates a cross-sectional view of the display module 230 taken along line B-B’ of FIGS. 11 or 12 .

FIG. 17 may be at least partially similar to FIG. 16. Hereinafter, for FIG. 17, the differences from FIG. 16 will be described. Accordingly, features not described with reference to FIG. 17 will be replaced with the description of FIG. 16.

FIG. 16 differs from FIG. 17 in that the conductive member 1610 is disposed between the waterproof tape 620 and the DDI 610.

According to an embodiment, the conductive member 1610 may be disposed between the waterproof tape 620 and the DDI 610. According to an embodiment, the FPCB 630 may include at least one first slit 1112a disposed to face the conductive member 1610. The first slit 1112a may form a discharge path for discharging static electricity introduced from the conductive member 1610 or the waterproof tape 620 to a ground of the FPCB 630, or to a shielding component (e.g., 1412 of FIG. 14) (e.g., a gasket) disposed on a support member (e.g., 1410 of FIG. 14).

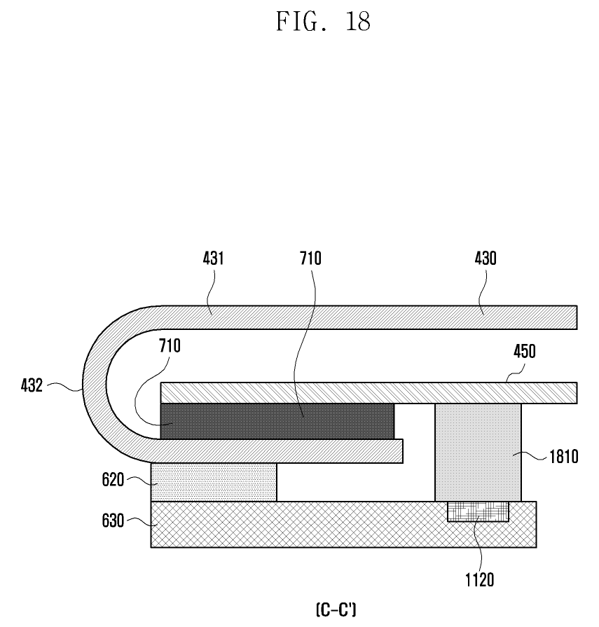

FIG. 18 is a partial cross-sectional view illustrating an example in which an FPCB 630 includes not only at least one first slit 1112a forming a discharge path for static electricity introduced into the FPCB 630, but also at least one third slit 1120 electrically connected to a conductive plate according to various embodiments. For example, FIG. 18 illustrates a cross-sectional view of the display module 230 taken along line C-C’ of FIGS. 11-13.

Referring to FIG. 18, the FPCB 630 according to an embodiment may include a grounding region that comes into contact with a rear surface of a support plate 450 through a conductive tape 1810. The grounding region of the FPCB 630 may correspond to a region along line C-C’ of FIGS. 11-13 and may be disposed to be spaced apart from the DDI 610. According to an embodiment, the FPCB 630 may also include a slit 1120 designed to form a discharge path in this grounding region. For example, a first cover layer of the FPCB 630 may include at least one third slit 1120 disposed adjacent to the conductive tape 1810 and exposing a portion of at least one metal layer.

According to an embodiment, the at least one third slit 1120 may be disposed in the first cover layer of the FPCB 630 and may at least partially overlap the conductive tape 1810 that is in contact with the rear surface of the support plate 450.

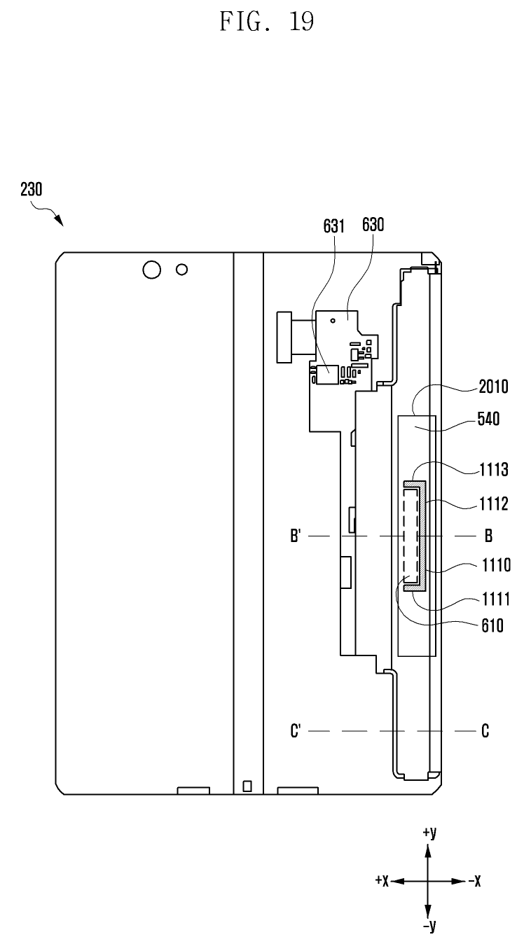

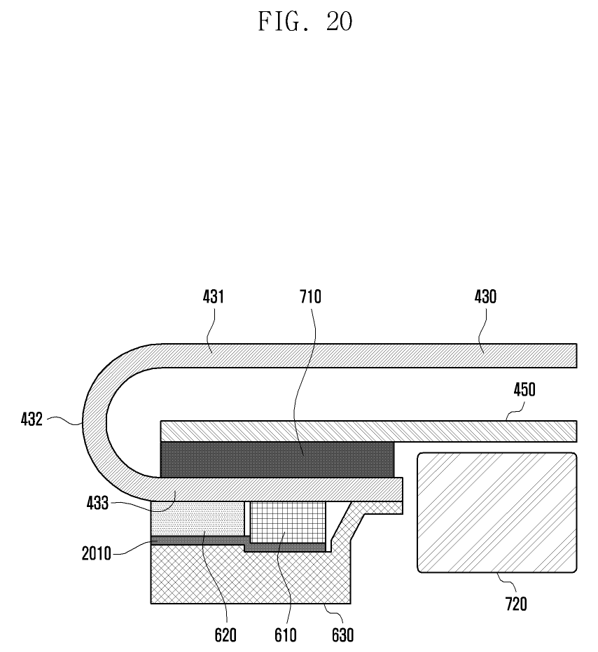

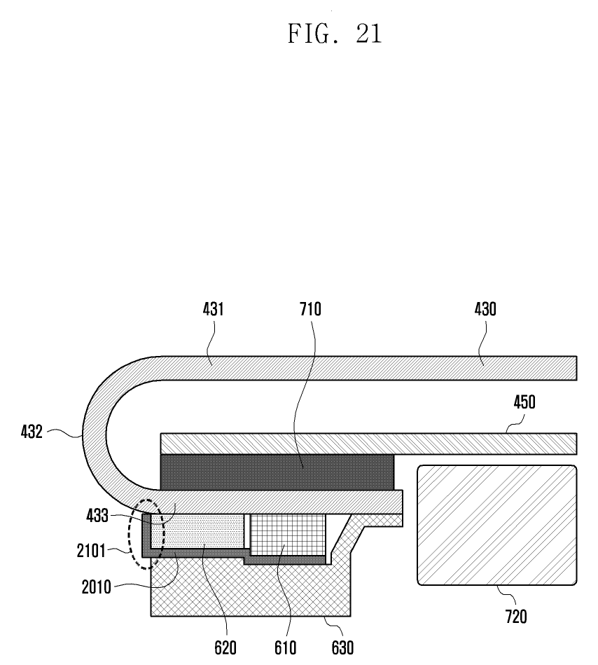

FIG. 19 is a diagram illustrating an example configuration of a rear surface of a display module 230 further including a cover member 2010 according to various embodiments. FIGS. 20 and 21 are partial cross-sectional views of an electronic device each illustrating edges of the display module 230 illustrated in FIG. 19 according to various embodiments.

Referring to FIGS. 19-21, the display module 230 according to an embodiment may include an FPCB 630 bonded in a reverse direction to a display panel 430, and a cover member 2010 disposed between the FPCB 630 and a DDI 610 to protect the DDI 610 from static electricity.

According to an embodiment, the FPCB 630 may be bonded to a portion of an extension region 433 of the display panel 430 and may extend in a first direction of the display module 230 in which a bending region 432 is located, thereby covering the DDI 610. One end of the FPCB 630 may be attached to the extension region 433 of the display panel 430 with a waterproof tape 620.

According to an embodiment, the display module 230 may further include the cover member 2010 disposed between the FPCB 630 and the DDI 610. The cover member 2010 may include at least one non-conductive layer and at least one conductive layer. An outer layer of the cover member 2010 may be formed of a non-conductive layer. For example, a stacked structure of the cover member 2010 may include a structure in which a non-conductive layer, a conductive layer, and a non-conductive layer are sequentially stacked.

Referring to FIGS. 19 and 20, a cover member 2010 according to an embodiment may include a first surface facing the front surface of the FPCB 630, including a first region and a second region. For example, the first surface of the cover member 2010 may include a first region disposed between the FPCB 630 and a DDI 610, and a second region extending from the first region and disposed between the FPCB 630 and a waterproof tape 620. In the illustrated embodiment, the cover member 2010 may protect the DDI 610 from static electricity even when lifting of the waterproof tape 620 occurs, by directly covering the DDI 610.

Referring to FIGS. 19 and 21, the cover member 2010 according to an embodiment may further include a second surface extending from the first surface facing the front surface of the FPCB 630 and covering a side surface of the waterproof tape 620. According to an embodiment, as denoted by reference numeral 2101 in FIG. 21, the second surface of the cover member 2010 may extend to a portion of a bending region 432 of the display panel 430 and may cover a portion of the bending region 432.

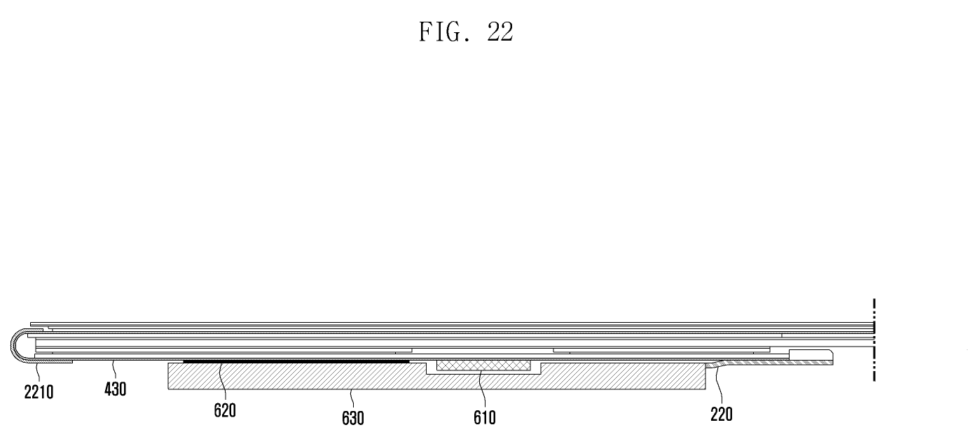

FIG. 22 is a partial cross-sectional view of an electronic device according to a comparative example illustrating an edge of a display module. For example, FIG. 22 may be a partial cross-sectional view of the display module according to the comparative example illustrated in FIG. 7. Accordingly, the comparative example illustrated in FIG. 22 may be identical or substantially identical to at least a portion of the comparative example illustrated in FIG. 7.

Referring to FIG. 22, the display module 230 according to the comparative example may include a display panel 430 configured to be bendable.

According to the comparative example, the display panel 430 may include an extension region (e.g., the extension region 433 of FIG. 7) that is bent downward so that a rear surface opposite to the front surface of the display panel 430 faces downward, and a DDI 610 may be disposed on the extension region.

According to the comparative example, an FPCB 630 may be connected to one end of the display panel 430 on which the DDI 610 is disposed, via an anisotropic conductive film (ACF) 220. The FPCB 630 may be bonded in a reverse direction to the display panel 430. The expression that the FPCB 630 is bonded in a reverse direction may refer, for example, to the FPCB 630 extending in a direction in which a bending region (e.g., the bending region 432 of FIG. 7) of the display panel 430, where the display panel 430 is bent, is located. According to the comparative example, the bending region (e.g., the bending region 432 of FIG. 7) of the display panel 430 may be covered with a bending protective member (e.g., a BPL; bending protective layer) 2210. The bending protective member 2210 may be used interchangeably with a term such as “bending protective film.” The bending protective member 2210 may serve as a protective layer that relieves physical stress that may occur in the bending region 432 of the display panel 430 and prevents/reduces damage to a circuit layer or a wiring layer, and may be formed of a flexible material. For example, the bending protective member 2210 may include a polymer film material such as polyimide (PI), polyethylene terephthalate (PET), polycarbonate (PC), or polyetherimide (PEI). The bending protective member 2210 may include a silicone-based elastomer or an epoxy resin.

According to the comparative example, the FPCB 630 may be bonded in a reverse direction to the display panel 430, may extend in a direction of the bending region of the display panel 430, and may cover the DDI 610, and an end of the FPCB 630 may be attached to the display panel 430 using a waterproof tape 620.

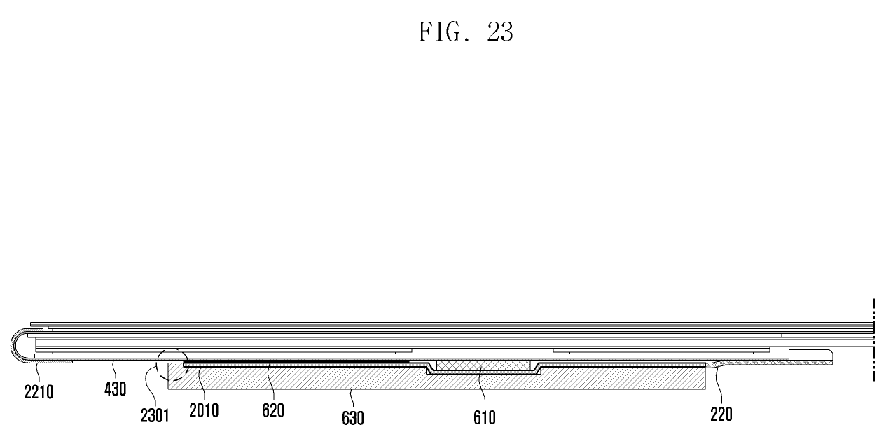

FIG. 23 is a partial cross-sectional view illustrating an edge of a display module of an electronic device according to various embodiments. For example, except for the features described below, the display module according to FIG. 23 may be at least partially identical to the display module according to the comparative example illustrated in FIG. 22. The display module according to FIG. 23 may be at least partially similar to the display module according to FIG. 20. Hereinafter, with reference to FIG. 23, the features of the display module that differ from those of FIG. 22 or are not described with reference to FIG. 23 will be described.

Referring to FIG. 23, according to an embodiment, the display module 230 may further include a cover member 2010 disposed between an FPCB 630 and a DDI 610. The cover member 2010 may include at least one non-conductive layer and at least one conductive layer. An outer layer of the cover member 2010 may be formed of a non-conductive layer. For example, a stacked structure of the cover member 2010 may include a structure in which a non-conductive layer, a conductive layer, and a non-conductive layer are sequentially stacked.

According to an embodiment, the cover member 2010 may cover the DDI 610 and the waterproof tape 620. Such a cover member 2010 may be covered by the FPCB 630. For example, the cover member 2010 may be disposed between the FPCB 630 and the DDI 610, and also between the FPCB 630 and the waterproof tape 620.

According to an embodiment, an end portion (e.g., 2301 in FIG. 23) of the FPCB 630 may extend to cover a side surface of the cover member 2010.

According to FIG. 23, the cover member 2010 and the FPCB 630 may not cover the bending protective member 2210.

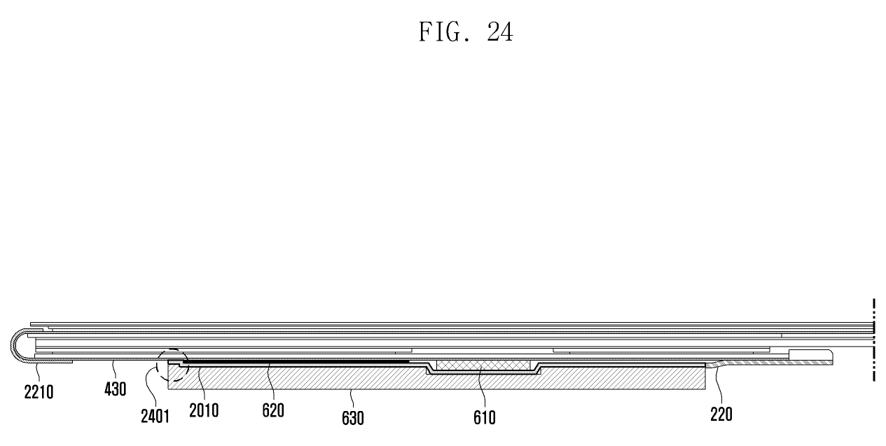

FIG. 24 is a partial cross-sectional view of an electronic device illustrating an edge of a display module according to various embodiments. For example, except for the features described below, the display module according FIG. 24 may be at least partially identical to the display module according to FIG. 23. The display module according to FIG. 24 may be at least partially similar to the display module according to FIG. 21. Hereinafter, with reference to FIG. 24, the features of the display module that differ from those of FIG. 23 or are not described with reference to FIG. 21 will be described.

Referring to FIG. 24, according to an embodiment, the cover member 2010 may cover the DDI 610 and the waterproof tape 620. Such a cover member 2010 may be covered by the FPCB 630. For example, the cover member 2010 may be disposed between the FPCB 630 and the DDI 610, and also between the FPCB 630 and the waterproof tape 620.

According to an embodiment, an end portion of the cover member 2010 corresponding to an end portion (e.g., 2401 of FIG. 24)of the FPCB 630 may extend to cover a side surface of the waterproof tape 620.

According to FIG. 24, the cover member 2010 and the FPCB 630 may not cover the bending protective member 2210.

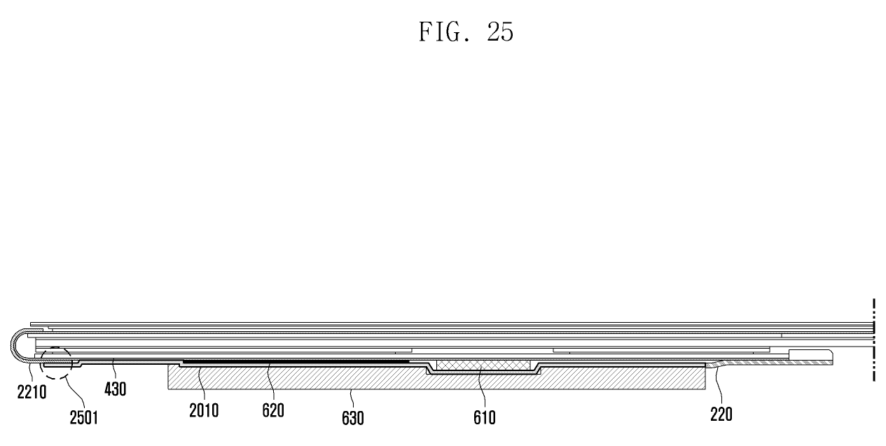

FIG. 25 is a partial cross-sectional view illustrating an edge of a display module of an electronic device according to various embodiments. For example, except for the features described below, the display module according to FIG. 25 may be at least partially identical to the display module illustrated in FIG. 23. Hereinafter, with reference to FIG. 25, features of the disclosure that differs from those of FIG. 23 will be described.

Referring to FIG. 25, according to an embodiment, a cover member 2010 may cover a DDI 610 and a waterproof tape 620. Such a cover member 2010 may be covered by the FPCB 630. For example, the cover member 2010 may be disposed between the FPCB 630 and the DDI 610, and also between the FPCB 630 and the waterproof tape 620.

According to FIG. 25, an end portion (e.g., 2501 FIG. 25) of the cover member 2010 may extend to cover a portion of a bending protective member 2210. The end portion (e.g., 2501 of FIG. 25) of the cover member 2010 extending to cover a portion of the bending protective member 2210 may not be covered by the FPCB 630.

According to an example embodiment, an electronic device may include a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and at least partially bent, and an extension region extending from the bending region to a rear surface of the display module. The display module may include a display driving circuit (display driver IC (DDI)) disposed on the extension region of the display panel, a flexible printed circuit board (FPCB) bonded to a portion of the extension region of the display panel and extending in a first direction of the display module in which the bending region is located to cover the display driving circuit, and a waterproof tape attaching one end of the FPCB to the extension region of the display panel. The FPCB may include a first cover layer forming a first surface facing the display driving circuit, a second cover layer forming a second surface opposite to the first surface, and at least one metal layer disposed between the first cover layer and the second cover layer. The first cover layer may include at least one first slit disposed adjacent to the display driving circuit and exposing a portion of the at least one metal layer.

The second cover layer of the FPCB may include at least one second slit disposed adjacent to the display driving circuit and exposing a portion of the at least one metal layer.

The at least one first slit and the at least one second slit may be at least partially overlapped with each other.

The display module may further include a conductive plate disposed on a rear surface of the display panel and a conductive tape attaching an opposite end of the FPCB to the conductive plate. The first cover layer of the FPCB may include at least one third slit disposed adjacent to the conductive tape and exposing a portion of the at least one metal layer.

The at least one first slit may be disposed between the display driving circuit and the bending region.

The at least one first slit may include a first portion disposed in a first direction in which the bending region is located from the display driving circuit, a second portion disposed in a second direction perpendicular to the first direction from the display driving circuit, and a third portion disposed in a third direction opposite to the second direction from the display driving circuit.

The at least one first slit may include at least one of a second portion disposed in a second direction perpendicular to the first direction from the display driving circuit where the bending region is located and a third portion disposed in a third direction opposite to the second direction from the display driving circuit.

According to an example embodiment, an electronic device may include a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and at least partially bent, and an extension region extending from the bending region to a rear surface of the display module. The display module may include a display driving circuit (display driver IC (DDI)) disposed on the extension region of the display panel, an FPCB bonded to a portion of the extension region of the display panel and extending in a first direction of the display module in which the bending region is located to cover the display driving circuit, a waterproof tape attaching one end of the FPCB to the extension region of the display panel, and a conductive member disposed adjacent to the waterproof tape.

The conductive member may be disposed in the first direction from the waterproof tape.

The conductive member may be disposed between the waterproof tape and the display driving circuit.

The conductive member may include at least one of a coating member including a conductive substance and a conductive material.

The FPCB may include a first cover layer forming a first surface facing the display driving circuit, a second cover layer forming a second surface opposite to the first surface, and at least one metal layer disposed between the first cover layer and the second cover layer. The first cover layer may include at least one first slit disposed to face the conductive member and exposing a portion of the at least one metal layer.

The second cover layer of the FPCB may include at least one second slit disposed adjacent to the display driving circuit and exposing a portion of the at least one metal layer.

The at least one first slit and the at least one second slit may be at least partially overlapped with each other.

The display module may further include a conductive plate disposed on a rear surface of the display panel and a conductive tape attaching an opposite end of the FPCB to the conductive plate. The first cover layer of the FPCB may include at least one third slit disposed adjacent to the conductive tape and exposing a portion of the at least one metal layer.

According to an example embodiment, an electronic device may include a first housing, a second housing foldably coupled to the first housing, and a display module supported by the first housing and the second housing and including a display panel configured to be bent about a folding axis formed by a hinge. The display panel may include a display region forming a front surface of the display module, a bending region extending from one end of the display region and at least partially bent, and an extension region extending from the bending region to a rear surface of the display module. The display module may include a display driving circuit (display driver IC (DDI)) disposed on the extension region of the display panel, an FPCB bonded to a portion of the extension region of the display panel and extending in a first direction of the display module in which the bending region is located to cover the display driving circuit, a waterproof tape attaching one end of the FPCB to the extension region of the display panel, and a cover member disposed between the FPCB and the display driving circuit.

The cover member may include a first surface facing a front surface of the FPCB, the first surface including a first region disposed between the FPCB and the display driving circuit, and a second region extending from the first region and disposed between the FPCB and the waterproof tape.

The cover member may include a second surface extending from the first surface facing the front surface of the FPCB and covering a side surface of the waterproof tape.

The second surface of the cover member may extend to a portion of the bending region to cover a portion of the bending region.

The cover member may include a stacked structure in which a non-conductive layer, a conductive layer, and another non-conductive layer are sequentially stacked.

While the disclosure has been illustrated and described with reference to various example embodiments, it will be understood that the various example embodiments are intended to be illustrative, not limiting. It will be further understood by those skilled in the art that various modifications, alternatives and/or variations of the various example embodiments may be made without departing from the true technical spirit and full technical scope of the disclosure, including the appended claims and their equivalents. It will also be understood that any of the embodiment(s) described herein may be used in conjunction with any other embodiment(s) described herein.

What is claimed is:

1. An electronic device comprising:
a first housing;
a second housing foldably coupled to the first housing; and
a display module supported by the first housing and the second housing and comprising a display panel configured to be bent about a folding axis formed by a hinge,
wherein the display panel comprises:
a display region forming a front surface of the display module;
a bending region extending from one end of the display region and configured to be at least partially bent; and
an extension region extending from the bending region to a rear surface of the display module,
wherein the display module comprises:
a display driving circuit disposed on the extension region of the display panel;
a flexible printed circuit board (FPCB) bonded to a portion of the extension region of the display panel and extending in a first direction of the display module in which the bending region is located to cover the display driving circuit; and
a waterproof tape attaching one end of the FPCB to the extension region of the display panel,
wherein the FPCB comprises:
a first cover layer forming a first surface facing the display driving circuit;
a second cover layer forming a second surface opposite to the first surface; and
at least one metal layer disposed between the first cover layer and the second cover layer, and
wherein the first cover layer comprises at least one first slit disposed adjacent to the display driving circuit and exposing a portion of the at least one metal layer.

2. The electronic device of claim 1, wherein the second cover layer of the FPCB comprises at least one second slit disposed adjacent to the display driving circuit and exposing a portion of the at least one metal layer.

3. The electronic device of claim 2, wherein the at least one first slit and the at least one second slit at least partially overlap each other.

4. The electronic device of claim 1, wherein the display module further comprises:
a conductive plate disposed on a rear surface of the display panel; and
a conductive tape attaching an opposite end of the FPCB to the conductive plate, and
wherein the first cover layer of the FPCB comprises at least one third slit disposed adjacent to the conductive tape and exposing a portion of the at least one metal layer.

5. The electronic device of claim 1, wherein the at least one first slit is disposed between the display driving circuit and the bending region.

6. The electronic device of claim 1, wherein the at least one first slit comprises:
a first portion disposed in a first direction in which the bending region is located from the display driving circuit;
a second portion disposed in a second direction perpendicular to the first direction from the display driving circuit; and
a third portion disposed in a third direction opposite to the second direction from the display driving circuit.

7. The electronic device of claim 1, wherein the at least one first slit comprises at least one of:
a second portion disposed in a second direction perpendicular to the first direction where the bending region is located from the display driving circuit; and
a third portion disposed in a third direction opposite to the second direction from the display driving circuit.

8. An electronic device comprising:
a first housing;
a second housing foldably coupled to the first housing; and
a display module supported by the first housing and the second housing and comprising a display panel configured to be bent about a folding axis formed by a hinge,
wherein the display panel comprises:
a display region forming a front surface of the display module;
a bending region extending from one end of the display region and configured to be at least partially bent; and
an extension region extending from the bending region to a rear surface of the display module, and
wherein the display module comprises:
a display driving circuit disposed on the extension region of the display panel;
a flexible printed circuit board (FPCB) bonded to a portion of the extension region of the display panel and extending in a first direction of the display module in which the bending region is located to cover the display driving circuit;
a waterproof tape attaching one end of the FPCB to the extension region of the display panel; and
a conductive member comprising a conductive material disposed adjacent to the waterproof tape.

9. The electronic device of claim 8, wherein the conductive member is disposed in the first direction from the waterproof tape.

10. The electronic device of claim 8, wherein the conductive member is disposed between the waterproof tape and the display driving circuit.

11. The electronic device of claim 8, wherein the conductive member comprises at least one of a coating member comprising a conductive substance and a conductive material.

12. The electronic device of claim 9, wherein the FPCB comprises:
a first cover layer forming a first surface facing the display driving circuit,
a second cover layer forming a second surface opposite to the first surface, and
at least one metal layer disposed between the first cover layer and the second cover layer, and
wherein the first cover layer comprises at least one first slit disposed to face the conductive member and exposing a portion of the at least one metal layer.

13. The electronic device of claim 12, wherein the second cover layer of the FPCB comprises at least one second slit disposed adjacent to the display driving circuit and exposing a portion of the at least one metal layer.

14. The electronic device of claim 13, wherein the at least one first slit and the at least one second slit at least partially overlap each other.

15. The electronic device of claim 12, wherein the display module further comprises:
a conductive plate disposed on a rear surface of the display panel; and
a conductive tape attaching an opposite end of the FPCB to the conductive plate, and
wherein the first cover layer of the FPCB comprises at least one third slit disposed adjacent to the conductive tape and exposing a portion of the at least one metal layer.

16. An electronic device comprising:
a first housing;
a second housing foldably coupled to the first housing; and
a display module supported by the first housing and the second housing and comprising a display panel configured to be bent about a folding axis formed by a hinge,
wherein the display panel comprises:
a display region forming a front surface of the display module;
a bending region extending from one end of the display region and configured to be at least partially bent; and
an extension region extending from the bending region to a rear surface of the display module, and
wherein the display module comprises:
a display driving circuit disposed on the extension region of the display panel;
a flexible printed circuit board (FPCB) bonded to a portion of the extension region of the display panel and extending in a first direction of the display module in which the bending region is located to cover the display driving circuit;
a waterproof tape attaching one end of the FPCB to the extension region of the display panel; and
a cover disposed between the FPCB and the display driving circuit.

17. The electronic device of claim 16, wherein the cover comprises a first surface facing a front surface of the FPCB and comprising:
a first region disposed between the FPCB and the display driving circuit; and
a second region extending from the first region and disposed between the FPCB and the waterproof tape.

18. The electronic device of claim 17, wherein the cover further comprises a second surface extending from the first surface facing the front surface of the FPCB and covering a side surface of the waterproof tape.

19. The electronic device of claim 18, wherein the second surface of the cover extends to cover a portion of the bending region.

20. The electronic device of claim 16, wherein the cover has a stacked structure in which a non-conductive layer, a conductive layer, and a non-conductive layer are sequentially stacked.
